(19) United States
(12) Patent Application Publication
(10) Pub. No.: US 2024/0297164 A1
(43) Pub. Date: Sep. 5, 2024

(54) DISPLAY DEVICE AND METHOD OF MANUFACTURING THE DISPLAY DEVICE

(71) Applicant: Samsung Display Co., LTD., Yongin-si (KR)

(72) Inventors: Soo Jo OCK, Yongin-si (KR); Hyun Deok IM, Yongin-si (KR); Buem Joon KIM, Yongin-si (KR); Won Ho LEE, Yongin-si (KR)

(73) Assignee: Samsung Display Co., LTD., Yongin-si (KR)

(21) Appl. No.: 18/461,743

(22) Filed: Sep. 6, 2023

(30) Foreign Application Priority Data
Mar. 2, 2023 (KR) 10-2023-0028038

(51) Int. Cl. H01L 25/16; H01L 25/075; H01L 33/62

(52) U.S. Cl. CPC H01L 25/167; H01L 25/0753; H01L 33/62; H01L 2933/0066

(57) ABSTRACT

A display device includes a base layer including an inner hole, a pixel circuit layer disposed on the base layer and including a pixel circuit, and a light emitting element disposed on the pixel circuit layer.

### CROSS REFERENCE TO RELATED APPLICATION(S)

This application claims priority to and benefits of Korean Patent Application No. 10-2023-0028038 under 35 U.S.C. § 119, filed on Mar. 2, 2023, in the Korean Intellectual Property Office (KIPO), the entire contents of which are incorporated herein by reference.

### BACKGROUND

### 1. Technical Field

The disclosure relates to a display device and a method of manufacturing the display device.

### 2. Description of the Related Art

In recent years, as interest in information display is increasing, research and development for a display device are continuously being conducted.

### SUMMARY

The disclosure provides a display device and a method of manufacturing the display device, in which reliability of performance of a pixel circuit may be reconsidered.

According to an embodiment of the disclosure, a display device may include a base layer including an inner hole, a pixel circuit layer disposed on the base layer and including a pixel circuit, and a light emitting element disposed on the pixel circuit layer.

According to an embodiment, the inner hole may form an air-pocket in the base layer.

According to an embodiment, the inner hole may form an interface with an inner surface of the base layer.

According to an embodiment, the pixel circuit layer may further include lower lines, at least a portion of the lower lines forming the pixel circuit. The display device may further include a line-free area in which the lower lines are not disposed. The inner hole and the line-free area may not overlap with each other in a plan view.

According to an embodiment, the display device may further include a first electrode and a second electrode spaced apart from each other on the pixel circuit layer, and an electrode-free area defined by a space between the first electrode and the second electrode. The light emitting element may be disposed between the first electrode and the second electrode in a plan view. The electrode-free area may be entirely disposed in the line-free area in a plan view.

According to an embodiment, the electrode-free area may overlap the light emitting element in a plan view.

According to an embodiment, the inner hole may be disposed between the lower lines and the electrode-free area in a plan view.

According to an embodiment, the pixel circuit may include a driving transistor. The inner hole may be disposed between the driving transistor and an emission area, in which the light emitting element is disposed, in a plan view.

According to an embodiment, the inner hole may include a first inner hole, a second inner hole, and a third inner hole. The pixel circuit may include a first pixel circuit, a second pixel circuit, and a third pixel circuit. The first inner hole, the second inner hole, and the third inner hole may be arranged in the first direction parallel to a direction the first pixel circuit, the second pixel circuit, and the third pixel circuit are sequentially arranged.

According to an embodiment, the emission area may include a first emission area, a second emission area, and a third emission area arranged in the first direction. The first inner hole may be disposed between the first pixel circuit and the first emission area in a plan view.

The second inner hole may be disposed between the second pixel circuit and the second emission area in a plan view. The third inner hole may be disposed between the third pixel circuit and the third emission area in a plan view.

According to an embodiment, the inner hole may have a shape extending in the first direction.

According to an embodiment, the inner hole may include more than one sub-inner holes sequentially arranged in the first direction.

According to an embodiment, the inner hole may include more than one sub-inner holes sequentially arranged in a second direction different from the first direction.

According to an embodiment of the disclosure, a display device may include a base layer, a light non-transmissive layer disposed on the base layer, a pixel circuit layer disposed on the base layer and including lower lines, at least a portion of the lower lines forming a pixel circuit, and a light emitting element disposed on the pixel circuit layer, and a line-free area in which the lower lines are not disposed. The light non-transmissive layer may be disposed in the line-free area adjacent to the pixel circuit.

According to an embodiment, the light non-transmissive layer may include a light absorbing material or a light reflecting material.

According to an embodiment, the display device may further include a first electrode and a second electrode spaced apart from each other on the pixel circuit layer, and an electrode-free area defined by a space between the first electrode and the second electrode. The light emitting element may be disposed between the first electrode and the second electrode in a plan view. The pixel circuit may include a driving transistor. The light non-transmissive layer may be disposed between the driving transistor and the electrode-free area in a plan view.

According to an embodiment of the disclosure, a method of manufacturing a display device may include preparing a base layer for manufacturing a display device, and forming an inner hole in the base layer.

According to an embodiment, the forming of the inner hole may include removing at least a portion of the base layer using a femtosecond laser.

According to an embodiment, the method may further include forming a pixel circuit layer including lower lines, at least a portion of which forming a pixel circuit on the base layer, patterning a first electrode and a second electrode on the pixel circuit layer, and arranging a light emitting element on the first electrode and the second electrode. The display device may include an electrode-free area in which the first electrode and the second electrode are spaced apart from each other. The pixel circuit may include a driving transistor. The inner hole may be disposed between the driving transistor and the electrode-free area in a plan view.

According to an embodiment, the arranging of the light emitting element may include forming an electric field between the first electrode and the second electrode, and aligning the light emitting element based on the electric field.

According to an embodiment of the disclosure, a display device and a method of manufacturing the display device, in which reliability of performance of a pixel circuit may be reconsidered may be provided.

### BRIEF DESCRIPTION OF THE DRAWINGS

The above and other features of the disclosure will become more apparent by describing in further detail embodiments thereof with reference to the accompanying drawings, in which:

FIG. 1 is a schematic perspective view illustrating a light emitting element according to an embodiment;

FIG. 2 is a schematic cross-sectional view illustrating a light emitting element according to an embodiment;

FIG. 3 is a schematic block diagram illustrating a display device according to an embodiment;

FIG. 4 is a schematic diagram of an equivalent circuit of a pixel circuit included in a sub-pixel according to an embodiment;

FIG. 5 is a schematic cross-sectional view illustrating a stacked structure of a display device according to an embodiment;

FIG. 6 is a schematic plan view illustrating a display device according to an embodiment;

FIG. 7 is a schematic cross-sectional view illustrating a display device according to an embodiment;

FIG. 8 is a schematic cross-sectional view illustrating a display device according to an embodiment;

FIGS. 9 to 11 are schematic cross-sectional views illustrating a structure of a display device including an inner hole according to an embodiment;

FIGS. 12 to 14 are schematic plan views illustrating a structure of a display device including an inner hole according to an embodiment;

FIG. 15 is a schematic cross-sectional view illustrating a structure of a display device including an inner hole according to an embodiment;

FIGS. 16 and 17 are schematic plan views illustrating a structure of a display device including an inner hole according to an embodiment;

FIG. 18 is a schematic cross-sectional view illustrating a structure of a display device including a light non-transmissive layer according to another embodiment;

FIG. 19 is a schematic cross-sectional view illustrating a structure of a display device including a light non-transmissive layer according to another embodiment;

FIG. 20 is a schematic plan view illustrating a structure of a display device including a light non-transmissive layer according to another embodiment;

FIGS. 21 and 22 are schematic cross-sectional views illustrating a method of manufacturing the display device according to an embodiment;

FIGS. 23 and 24 are schematic cross-sectional views illustrating a method of manufacturing the display device according to another embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure comprises all modifications, equivalents, and substitutions within the spirit and technical scope of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise.

Terms of “first,” “second,” and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions comprise plural expressions unless the context clearly dictates in an embodiment.

It should be understood that in the application, a term of “comprise,” “include,” “have,” or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it comprises not only a case where the portion is “directly on” another portion, but also an embodiment where there is further another portion between the portion and the other portion. In contrast, when an element is referred to as being “directly on” another element, no intervening elements are present. In addition, in the specification, in case that a portion of a layer, a layer, an area, a plate, or the like is formed on another portion, a forming direction is not limited to an upper direction but comprises forming the portion on a side surface or in a lower direction. On the contrary, in case that a portion of a layer, a layer, an area, a plate, or the like is formed “under” another portion, this comprises not only a case where the portion is “directly beneath” another portion but also a case where there is further another portion between the portion and the other portion.

Spatially relative terms, such as “under,” “lower,” “upper,” “over,” “side” (for example, as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (for example, rotated 90 degrees or at other orientations), and, as such, the spatially relative descriptors used herein interpreted accordingly.

When an element, such as a layer, film, region, or substrate is referred to as being “on” or “connected to” another element, it may be directly on, connected to, or coupled to the other element or intervening elements may be present. When, however, an element or layer is referred to as being “directly on” or “directly connected to” another element or layer, there are no intervening elements or layers present. To this end, the term “connected” may refer to physical, electrical, and/or fluid connection, with or without intervening elements. Further, the first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another. For the purposes of this disclosure, “at least one of X, Y, and Z” may be construed as X only, Y only, Z only, or any combination of two or more of X, Y, and Z, such as, for instance, XYZ, XYY, YZ, and ZZ. As used herein, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

When a component is described herein to “connect” another component to the other component or to be “connected to” other components, the components may be connected to each other as separate elements, or the components may be integral with each other.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some example embodiments may be physically separated into two or more interacting and discrete blocks, units, and/or modules without departing from the scope of the disclosure. Further, the blocks, units, and/or modules of some example embodiments may be physically combined into more complex blocks, units, and/or modules without departing from the scope of the disclosure.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The display surface may be parallel to a surface defined by a first direction DR1 and a second direction DR2. A normal direction of the display surface, i.e., a thickness direction of the display device DD, may indicate a third direction DR3. In this specification, an expression of “when viewed from a plane or in a plan view” may represent a case when viewed in the third direction DR3. Hereinafter, a front surface (or a top surface) and a rear surface (or a bottom surface) of each of layers or units may be distinguished by the third direction DR3. However, directions indicated by the first to third directions DR1, DR2, and DR3 may be a relative concept, and converted with respect to each other, e.g., converted into opposite directions.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The disclosure relates to a display device DD and a method of manufacturing the display device. Hereinafter, a display device DD and a method of manufacturing the display device according to an embodiment are described with reference to the accompanying drawings.

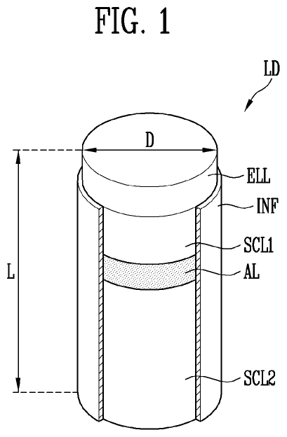

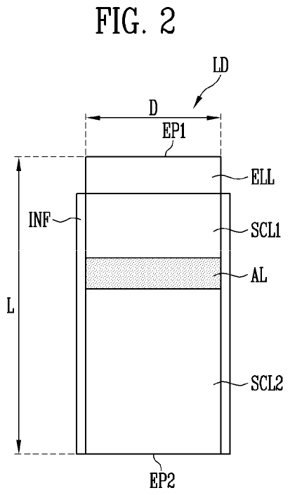

A light emitting element LD according to an embodiment is described with reference to FIGS. 1 and 2. FIG. 1 is a schematic perspective view illustrating a light emitting element LD according to an embodiment. FIG. 2 is a schematic cross-sectional view illustrating a light emitting element LD according to an embodiment.

The light emitting element LD may emit light. The light emitting element LD may include a first semiconductor layer SCL1, a second semiconductor layer SCL2, and an active layer AL disposed between the first semiconductor layer SCL1 and the second semiconductor layer SCL2. According to an embodiment, the first semiconductor layer SCL1, the active layer AL, and the second semiconductor layer SCL2 may be sequentially stacked in a length L direction of the light emitting element LD. According to an embodiment, the light emitting element LD may further include an electrode layer ELL and an insulating film INF.

The light emitting element LD may have various shapes. For example, the light emitting element LD may have a column shape extending in a direction. The column shape may be a rod-like shape or a bar-like shape extending in the length L direction (for example, an aspect ratio may be greater than about 1), such as a circular column, a polygonal column, or the like, but a cross-sectional shape of the column shape is not particularly limited thereto.

The light emitting element LD may have a first end EP1 and a second end EP2. According to an embodiment, the first semiconductor layer SCL1 may be disposed adjacent to the first end EP1 of the light emitting element LD, and the second semiconductor layer SCL2 may be disposed adjacent to the second end EP2. According to an embodiment, an electrode layer ELL may be disposed adjacent to the first end EP1.

The light emitting element LD may be manufactured by etching sequentially stacked semiconductor layers. The light emitting element LD may have a size in a range of a nano scale to a micro scale. For example, a diameter D (or a width) of each of the light emitting element LD and a length L of each of the light emitting element LD may be in a range of a nano scale to a micro scale. However, the disclosure is not necessarily limited thereto.

The first semiconductor layer SCL1 may include a first conductivity type semiconductor. The first semiconductor layer SCL1 may be disposed on the active layer AL and may include a semiconductor layer of a type. The type of the first semiconductor layer SCL1 and a type of the second semiconductor layer SCL2 may be different from each other. For example, the first semiconductor layer SCL1 may be a P-type semiconductor layer. For example, the first semiconductor layer SCL1 may include at least one semiconductor material of InAlGaN, GaN, AlGaN, InGaN, AlN, and InN, and may be doped with a first conductivity type dopant such as Ga, B, Mg, and the like. However, the disclosure is not limited thereto. The first semiconductor layer SCL1 may include various materials.

The active layer AL may be disposed between the first semiconductor layer SCL1 and the second semiconductor layer SCL2. The active layer AL may have a single-quantum well or multi-quantum well structure. A position of the active layer AL is not limited thereto and may be variously changed depending on a type of the light emitting element LD.

A clad layer (not shown) doped with a conductive dopant may be formed on a side and/or another side of the active layer AL. For example, the clad layer may include at least one of AlGaN and InAlGaN. However, the disclosure is not necessarily limited thereto.

The second semiconductor layer SCL2 may include a second conductivity type semiconductor. The second semiconductor layer SCL2 may be disposed on the active layer AL and may include a semiconductor layer of a type. The type of the second semiconductor layer SCL2 and the type of the first semiconductor layer SCL1 may be different from each other. For example, the second semiconductor layer SCL2 may include an N-type semiconductor layer. For example, the second semiconductor layer SCL2 may include at least one of InAlGaN, GaN, AlGaN, InGaN, AlN, and InN, and may be doped with a second conductivity type dopant such as Si, Ge, Sn, and the like. However, the disclosure is not limited thereto. The second semiconductor layer SCL2 may include various materials.

In case that a voltage equal to or greater than a threshold voltage is applied to the first end EP1 and the second end EP2 of the light emitting element LD, an electron-hole pair may recombine with each other in the active layer AL, and the light emitting element LD may emit light. By controlling light emission of the light emitting element LD using such a principle, the light emitting element LD may be used as a light source in various devices.

The insulating film INF may be disposed on a surface (for example, a side surface) of the light emitting element LD. The insulating film INF may surround an outer surface (for example, an outer side surface) of the active layer AL, and may further surround a portion of each of the first semiconductor layer SCL1 and the second semiconductor layer SCL2. The insulating film INF may have a single layer or multiple layer structure.

The insulating film INF may expose the first end EP1 and the second end EP2 of the light emitting element LD having different polarities. For example, the insulating film INF may expose an end of the electrode layer ELL disposed adjacent to the first end EP1 and an end of the second semiconductor layer SCL2 disposed adjacent to the second end EP2 of the light emitting element LD. The insulating film INF may ensure electrical stability of the light emitting element LD. The insulating film INF may minimize a surface defect of the light emitting element LD to improve lifespan and efficiency. In case that multiple light emitting elements LD are disposed close to each other, the insulating film INF may prevent a short defect between adjacent the light emitting elements LD.

According to an embodiment, the insulating film INF may include at least one of silicon oxide (SiOₓ), silicon nitride (SiNₓ), silicon oxynitride (SiOₓN_{y}), aluminum oxide (AlₓO_{y}), and titanium oxide (TiOₓ). However, the insulating film INF is not necessarily limited thereto.

The electrode layer ELL may be disposed on the first semiconductor layer SCL1. The electrode layer ELL may be disposed adjacent to the first end EP1. The electrode layer ELL may be electrically connected to the first semiconductor layer SCL1. A portion of the electrode layer ELL may be exposed. For example, the insulating film INF may expose a surface of the electrode layer ELL. The electrode layer ELL may be exposed in an area corresponding to the first end EP1. According to an embodiment, a side surface of the electrode layer ELL may be exposed. For example, the insulating film INF may cover side surfaces of each of the first semiconductor layer SCL1, the active layer AL, and the second semiconductor layer SCL2, and may not cover at least a portion of the side surface of the electrode layer ELL. The electrode layer ELL disposed adjacent to the first end EP1 may be readily connected to another configuration (or another component). According to an embodiment, the insulating film INF may expose a portion of the side surface of the first semiconductor layer SCL1 and/or the second semiconductor layer SCL2 as well as the side surface of the electrode layer ELL.

According to an embodiment, the electrode layer ELL may be an Ohmic contact electrode. However, the disclosure is not necessarily limited thereto. In another embodiment, the electrode layer ELL may be a Schottky contact electrode or the like.

According to an embodiment, the electrode layer ELL may include at least one of chromium (Cr), titanium (Ti), aluminum (Al), gold (Au), nickel (Ni), an oxide thereof, and an alloy thereof. However, the disclosure is not necessarily limited thereto. According to an embodiment, the electrode layer ELL may be transparent (for example, substantially transparent). For example, the electrode layer ELL may include indium tin oxide (ITO) or the like. Accordingly, the electrode layer ELL may transmit emitted light.

A structure, a shape, or the like of the light emitting element LD is not limited thereto, and the light emitting element LD may have various structures, shapes, and the like according to an embodiment. For example, the light emitting element LD may further include an electrode layer (for example, an additional electrode layer) disposed on a surface of the second semiconductor layer SCL2 adjacent to the second end EP2.

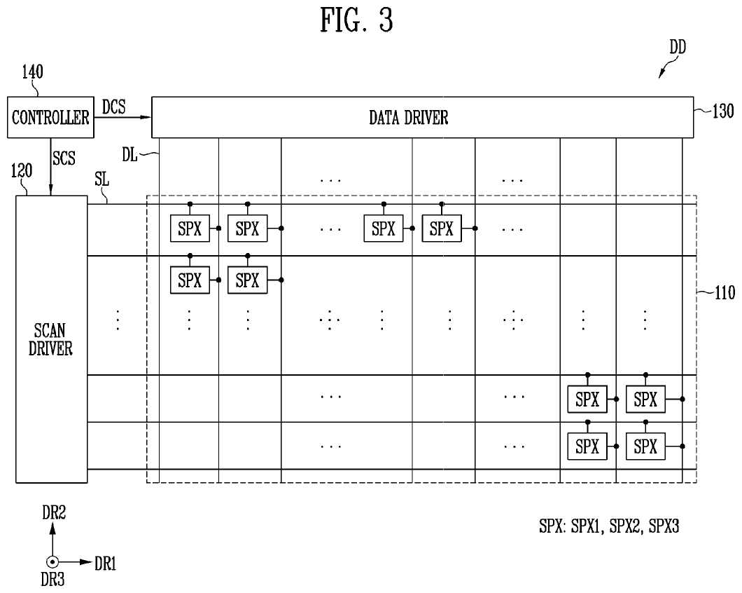

A display device DD according to an embodiment is described with reference to FIG. 3. FIG. 3 is a schematic block diagram illustrating a display device DD according to an embodiment.

The display device DD may emit light. The display device DD may be an electronic device using the light emitting element LD as a light source. According to an embodiment, the display device DD may include a pixel unit 110, a scan driver 120, a data driver 130, and a controller 140.

The pixel unit 110 may include multiple sub-pixels SPX electrically connected to a scan line SL and a data line DL. According to an embodiment, one or more of the sub-pixels SPX may form (or configure) a pixel (or a pixel unit 110). Each of the sub-pixels SPX may be one of a first sub-pixel SPX1, a second sub-pixel SPX2, and a third sub-pixel SPX3. For example, the sub-pixels SPX may include the first sub-pixel SPX1 emitting light of a first color (for example, red), a second sub-pixel SPX2 emitting light of a second color (for example, green), and a third sub-pixel SPX3 emitting light of a third color (for example, blue). However, the disclosure is not limited thereto.

The scan driver 120 may be disposed on a side of the pixel unit 110. The scan driver 120 may receive a first control signal SCS from the controller 140. The scan driver 120 may provide a scan signal (for example, a first scan signal or a second scan signal) to the sub-pixel SPX. The scan driver 120 may supply the scan signal to the scan line SL in response to the first control signal SCS.

The first control signal SCS may be a signal for controlling a driving timing of the scan driver 120. The first control signal SCS may include a scan start signal and multiple clock signals for the scan signal. The scan signal may be set to a gate-on level corresponding to a type of a transistor to which a corresponding scan signal is supplied.

The data driver 130 may be disposed on a side of the pixel unit 110. For example, the scan driver 120 may be disposed on a side of the pixel unit 110, and the data driver may be disposed on another side of the pixel unit 110. The data driver 130 may receive a second control signal DCS from the controller 140. The data driver 130 may provide a data signal to the sub-pixel SPX. The data driver 130 may supply the data signal to the data line DL in response to the second control signal DCS. For example, the second control signal DCS may be provided to the sub-pixel SPX through the data line DL. The second control signal DCS may be a signal for controlling a driving timing of the data driver 130.

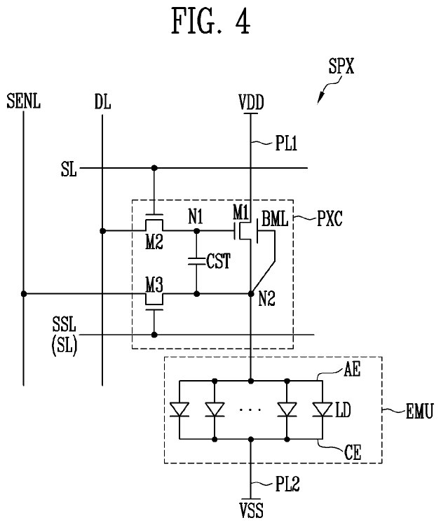

According to an embodiment, the display device DD may further include a compensator (not shown). The compensator may receive a third control signal for sensing and deterioration compensation of the sub-pixels SPX from the controller 140. The compensator may receive a sensing value (for example, current information or voltage information) from the sub-pixel SPX through a sensing line SENL (see, e.g., FIG. 4). The compensator may generate a compensation value for compensating for deterioration of the sub-pixel SPX based on the sensing value.

A portion of the scan line SL may extend in a pixel row direction (for example, in a first direction DR1) and may be electrically connected to the sub-pixel SPX of a corresponding pixel row through another portion of the scan line SL extending in a second direction DR2. The second direction DR2 and the first direction DR1 may be different. For example, the second direction DR2 may intersect the first direction DR1. Accordingly, the scan line SL may supply the scan signal to the sub-pixel SPX (for example, the corresponding or connected sub-pixel SPX).

The data line DL may extend in a pixel column direction (for example, in the second direction DR2) and may be electrically connected to the sub-pixel SPX. The data line DL may supply the data signal to the sub-pixel SPX (for example, the connected sub-pixel SPX).

The pixel row direction may be a horizontal direction and may be the first direction DR1. The pixel column direction may be a vertical direction and may be the second direction DR2.

In FIG. 3, the scan driver 120, the data driver 130, and the controller 140 are shown separately, but at least a portion of the scan driver 120, the data driver 130, or the controller 140 may be integrated into a module (for example, a driver module), integrated circuit (IC) chip, or the like.

FIG. 4 is a schematic diagram of an equivalent circuit of a pixel circuit PXC included in a sub-pixel SPX according to an embodiment. Referring to FIG. 4, the sub-pixel SPX may include a pixel circuit PXC. The pixel circuit PXC may drive a light emitting unit EMU (or the light emitting elements LD). Each of the sub-pixels SPX for forming a pixel unit 110 (see, e.g., FIG. 3) may include a pixel circuit PXC.

The pixel circuit PXC may be electrically connected to the scan line SL, the data line DL, a first power line PL1, and a second power line PL2.

The sub-pixel SPX may include a light emitting unit EMU (or a light emitting elements LD) that emits light corresponding to the data signal provided from the data line DL.

The pixel circuit PXC may be disposed between the first power line PL1 and the light emitting unit EMU. The pixel circuit PXC may be electrically connected to the scan line SL to which the first scan signal is supplied and the data line DL to which the data signal is supplied. The pixel circuit PXC may be electrically connected to a scan control line SSL to which a second scan signal is supplied, and may be electrically connected to a reference power (or initialization power) or the sensing line SENL connected to a sensing circuit. According to an embodiment, the second scan signal and the first scan signal may be the same or different. In case that the second scan signal and the first scan signal are the same, the scan control line SSL may be integrated with the scan line SL. The sensing line SENL may be an initialization power line.

The pixel circuit PXC may include one or more circuit elements. For example, the pixel circuit PXC may include a first transistor M1, a second transistor M2, a third transistor M3, and a storage capacitor CST.

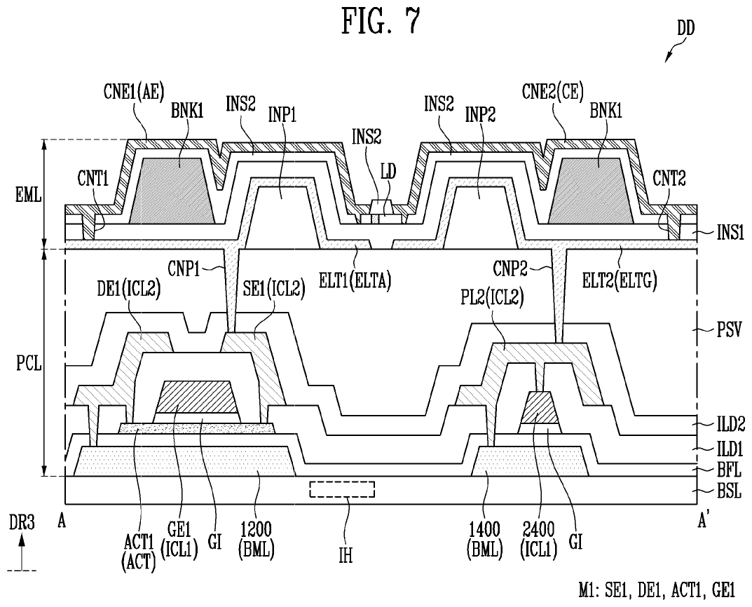

The first transistor M1 may be electrically connected between the first power line PL1 and a second node N2. The second node N2 may be a node to which the pixel circuit PXC and the light emitting unit EMU are connected. For example, the second node N2 may be a node to which a first source electrode SE1 (see, e.g., FIG. 7) of the first transistor M1 and an anode connection electrode AE of the light emitting unit EMU are connected. A first gate electrode GE1 (see, e.g., FIG. 7) of the first transistor M1 may be electrically connected to a first node N1. The first transistor M1 may control a driving current supplied to the light emitting unit EMU in response to a voltage of the first node N1. The first transistor M1 may be a driving transistor.

According to an embodiment, a portion of a lower auxiliary electrode layer BML (for example, a first lower auxiliary electrode layer 1200 in FIG. 7) may be disposed under the first transistor M1, and back-bias technology for moving a threshold voltage of the first transistor M1 in a negative direction or a positive direction by applying a back-bias voltage to the first lower auxiliary electrode layer 1200 while driving the sub-pixel SPX (or sync technology) may be applied.

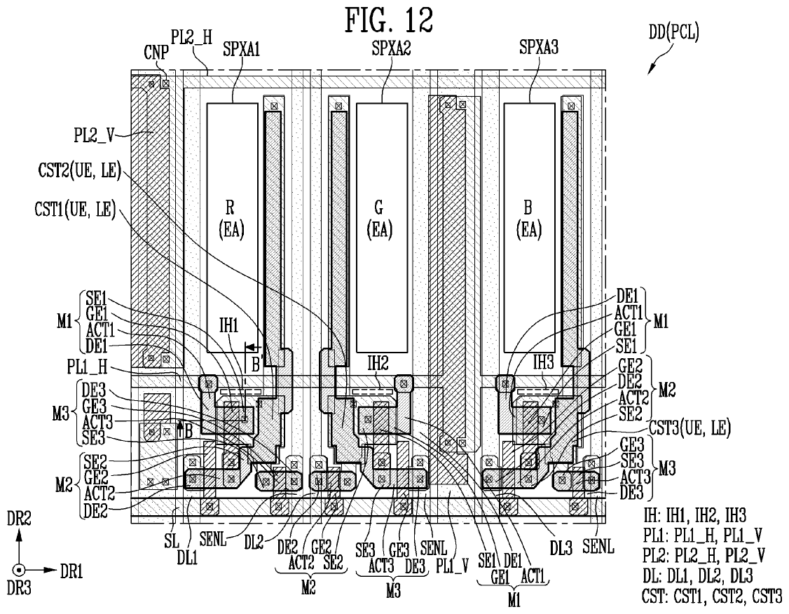

The second transistor M2 may be electrically connected between the data line DL and the first node N1. A second gate electrode GE2 (see, e.g., FIG. 12) of the second transistor M2 may be electrically connected to the scan line SL. The second transistor M2 may be turned on in case that a first scan signal of a gate-on voltage (for example, a high level voltage) is supplied from the scan line SL, to electrically connect the data line DL and the first node N1.

For each frame period, a data signal of a corresponding frame may be supplied to the data line DL, and the data signal may be supplied to the first node N1 through the second transistor M2 during a period in which the first scan signal of the gate-on voltage is supplied. The second transistor M2 may be a switching transistor for supplying each data signal to the sub-pixel SPX.

An electrode of the storage capacitor CST may be electrically connected to the first node N1 and another electrode of the storage capacitor CST may be electrically connected to the second node N2. The storage capacitor CST may be charged with a voltage corresponding to the data signal supplied to the first node N1 during each frame period.

The third transistor M3 may be electrically connected between the second node N2 and the sensing line SENL. A third gate electrode GE3 (see, e.g., FIG. 12) of the third transistor M3 may be connected to the scan control line SSL (or the scan line SL). The third transistor M3 may be turned on in case that a second scan signal (or a first scan signal) of a gate-on voltage (for example, a high level voltage) is supplied from the scan control line SSL, to supply a reference voltage (or an initialization voltage) from the sensing line SENL to the second node N2, or supply a voltage of the second node N2 to the sensing line SENL. The voltage of the second node N2 supplied to a sensing circuit through the sensing line SENL may be provided to an external circuit (for example, the controller 140) to be used for compensating for a characteristic deviation of the sub-pixels SPX.

In FIG. 4, all of the transistors M1, M2, and M3 included in the pixel circuit PXC are illustrated as N-type transistors, but the disclosure is not limited thereto. For example, at least one of the first, second, and third transistors M1, M2, and M3 may be a P-type transistor. Also, a structure and a driving method of the sub-pixel SPX may be variously changed.

The light emitting unit EMU may include the anode connection electrode AE, a cathode connection electrode CE, and one or more light emitting elements LD electrically connected between the first power line PL1 and the second power line PL2. For example, the light emitting unit EMU may include the anode connection electrode AE connected to the first power line PL1 through the first transistor M1, the cathode connection electrode CE connected to the second power line PL2, and one or more light emitting elements LD connected between the anode connection electrode AE and the cathode connection electrode CE. According to an embodiment, the light emitting unit EMU may include multiple light emitting elements LD connected in parallel between the anode connection electrode AE and the cathode connection electrode CE.

Power of the first power line PL1 and power of the second power line PL2 may have different potentials. For example, the first power line PL1 may be electrically connected to high-potential pixel power VDD to receive high-potential power, and the second power line PL2 may be electrically connected to low-potential power (for example, low-potential pixel power) VSS to receive low-potential power. A potential difference between the power of the first power line PL1 and the power of the second power line PL2 (for example, a potential difference between the high-potential power VDD and the low-potential power VSS) may be set to equal to or greater than a threshold voltage of the light emitting elements LD.

The first power line PL1 may be electrically connected to the first transistor M1. The second power line PL2 may be electrically connected to the cathode connection electrode CE.

Each light emitting element LD may be connected in a forward direction between the first power line PL1 and the second power line PL2 to form each effective light source. These effective light sources may be gathered to form the light emitting unit EMU of the sub-pixel SPX.

The light emitting elements LD may emit light with a luminance corresponding to the driving current supplied from the pixel circuit PXC. During each frame period, the pixel circuit PXC may supply a driving current corresponding to the data signal to the light emitting unit EMU. The driving current supplied to the light emitting unit EMU may be divided and flowed to the light emitting elements LD. Accordingly, while each light emitting element LD emits light with a luminance corresponding to the current flowing through each light emitting element LD, the light emitting unit EMU may emit light with a luminance corresponding to the driving current.

Although FIG. 4 illustrates an embodiment in which the sub-pixel SPX includes a light emitting unit EMU of a parallel structure is disclosed, the disclosure is not limited thereto. For example, the sub-pixel SPX may include a light emitting unit EMU of a series structure or a series/parallel structure. The pixel circuit PXC for the sub-pixel SPX is not limited thereto. According to an embodiment, the pixel circuit PXC may include seven transistors and one storage capacitor.

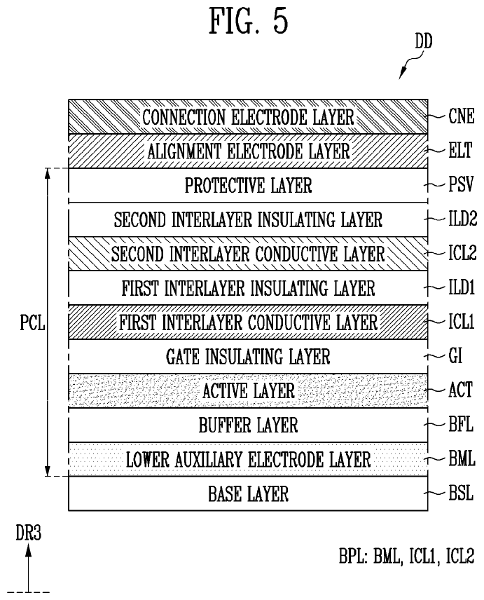

Hereinafter, a display device DD according to an embodiment is described with reference to FIGS. 5 to 17.

In the display device DD according to an embodiment, a base layer BSL, which may form a base of the display device DD, may include an inner hole IH.

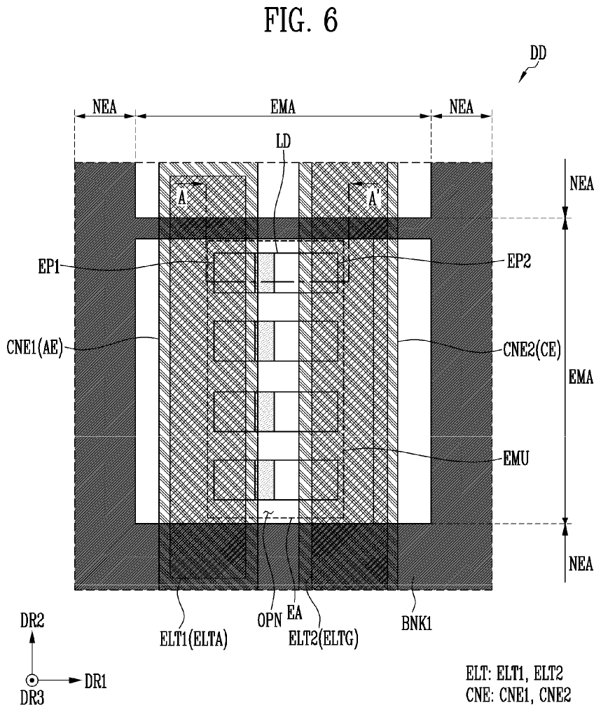

Referring to FIG. 5, a stacked structure included in the display device DD is described. FIG. 5 is a schematic cross-sectional view illustrating a stacked structure of a display device DD according to an embodiment. In FIGS. 6 to 17, same layers as the layers (for example, BSL, BML, BFL, ACT, GI, ICL1, ILD1, ICL2, ILD2, PSV, ELT, and CNE) described above with reference to FIG. 5 (for example, patterning in a same process) may be expressed by a same hatching.

Referring to FIG. 5, the stacked structure included in the display device DD according to an embodiment may have a shape in which at least a portion is patterned in a structure in which the base layer BSL, the lower auxiliary electrode layer BML, a buffer layer BFL, an active layer ACT, a gate insulating layer GI, a first interlayer conductive layer ICL1, a first interlayer insulating layer ILD1, a second interlayer conductive layer ICL2, a second interlayer insulating layer ILD2, a protective layer PSV, an alignment electrode layer ELT, and a connection electrode layer CNE are sequentially stacked.

According to an embodiment, the lower auxiliary electrode layer BML, the buffer layer BFL, the active layer ACT, the gate insulating layer GI, the first interlayer conductive layer ICL1, the first interlayer insulating layer ILD1, the second interlayer conductive layer ICL2, the second interlayer insulating layer ILD2, and the protective layer PSV may form (or be included in) a pixel circuit layer PCL of the pixel circuits PXC. According to an embodiment, the lower auxiliary electrode layer BML, the first interlayer conductive layer ICL1, and the second interlayer conductive layer ICL2 may form (or be included in) lower lines BPL. The lower lines BPL may be lines forming (or included in) the pixel circuit layer PCL, and may include lines (for example, wires or electrodes) formed lower than the alignment electrode layer ELT.

The base layer BSL may form (or configure) a base surface of the display device DD. The base layer BSL may be a rigid, a flexible substrate or film, or the like. For example, the base layer BSL may be a glass substrate. A material or a configuration of the base layer BSL is not limited thereto, and the base layer BSL may include various materials.

The buffer layer BFL may prevent diffusion of an impurity or moisture permeation into the active layer ACT. According to an embodiment, the buffer layer BFL may include at least one of silicon nitride (SiNₓ), silicon oxide (SiOₓ), silicon oxynitride (SiOₓN_{y}), and aluminum oxide (AlₓO_{y}). However, the disclosure is not necessarily limited thereto.

The active layer ACT may include a semiconductor. For example, the active layer ACT may include at least one of polysilicon, low temperature polycrystalline silicon (LTPS), amorphous silicon, and an oxide semiconductor. According to an embodiment, the active layer ACT may form a channel of the first transistor M1, the second transistor M2, and the third transistor M3, and an impurity may be doped in a portion contacting source/drain electrodes (for example, a first source electrode SE1 and a first drain electrode DE1 of FIG. 7).

The lower auxiliary electrode layer BML, the first interlayer conductive layer ICL1, the second interlayer conductive layer ICL2, the alignment electrode layer ELT, and the connection electrode layer CNE may include a conductive material.

According to an embodiment, each of the lower auxiliary electrode layer BML, the first interlayer conductive layer ICL1, and the second interlayer conductive layer ICL2 may include one or more conductive layers. According to an embodiment, each of the lower auxiliary electrode layer BML, the first interlayer conductive layer ICL1, and the second interlayer conductive layer ICL2 may include at least one of gold (Au), silver (Ag), aluminum (Al), molybdenum (Mo), chromium (Cr), titanium (Ti), nickel (Ni), neodymium (Nd), copper (Cu), and platinum (Pt). However, the disclosure is not necessarily limited thereto.

The gate insulating layer GI, the first interlayer insulating layer ILD1, the second interlayer insulating layer ILD2, and the protective layer PSV may electrically separate the active layer ACT, the first interlayer conductive layer ICL1, the second interlayer insulating layer ICL2, and the alignment electrode layer ELT from each other. According to an embodiment, the conductive layers (for example, ACT, ICL1, ICL2, and ELT) may be electrically connected to each other through contact hole(s) formed in one or more of the gate insulating layer GI, the first interlayer insulating layer ILD1, the second interlayer insulating layer ILD2, and the protective layer PSV.

According to an embodiment, the gate insulating layer GI, the first interlayer insulating layer ILD1, and the second interlayer insulating layer ILD2 may include an inorganic material. For example, the inorganic material may include at least one of silicon nitride (SiNₓ), silicon oxide (SiOₓ), silicon oxynitride (SiOₓN_{y}), and aluminum oxide (AlₓO_{y}). According to an embodiment, the protective layer PSV may include an organic material. For example, the organic material may include at least one of an acrylic resin, an epoxy resin, a phenol resin, a polyamide resin, a polyimide resin, a polyester resin, a polyphenylene sulfide resin, and benzocyclobutene (BCB). However, the disclosure is not necessarily limited thereto.

According to an embodiment, the alignment electrode layer ELT may include a conductive material. For example, the alignment electrode layer ELT may include at least one of molybdenum (Mo), magnesium (Mg), silver (Ag), platinum (Pt), palladium (Pd), gold (Au), nickel (Ni), neodymium (Nd), iridium (Ir), chromium (Cr), titanium (Ti), copper (Cu), and aluminum (Al). However, the disclosure is not necessarily limited thereto.

According to an embodiment, the connection electrode layer CNE may include a conductive material. The connection electrode layer CNE may be electrically connected to the light emitting element LD. According to an embodiment, the connection electrode layer CNE may include a transparent conductive material. For example, the connection electrode layer CNE may include at least one of indium tin oxide (ITO), indium zinc oxide (IZO), and indium tin zinc oxide (ITZO). However, the disclosure is not necessarily limited thereto. A first insulating layer INS1 (see, e.g., FIG. 7) may be disposed between the alignment electrode layer ELT and the connection electrode layer CNE.

A schematic planar structure and a schematic cross-sectional structure of a display device DD according to an embodiment is described with reference to FIGS. 6 to 8.

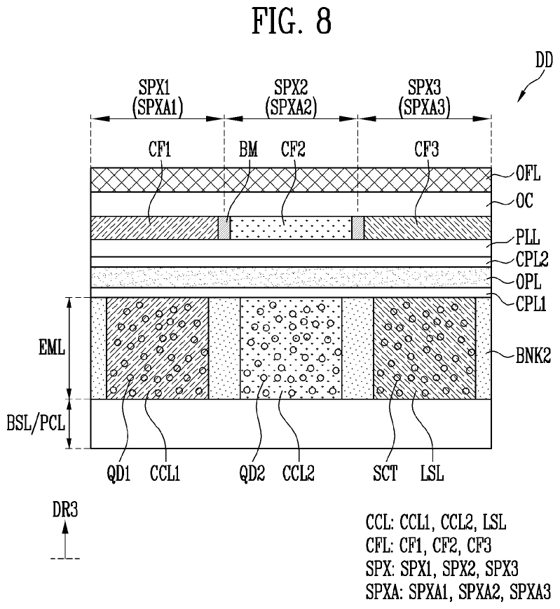

FIGS. 6 to 8 are schematic diagrams illustrating a display device DD according to an embodiment. FIG. 6 is a schematic plan view illustrating a display device DD according to an embodiment. FIG. 7 is a schematic cross-sectional view illustrating a display device DD according to an embodiment. FIG. 7 is a schematic cross-sectional view taken along line A-A′ of FIG. 6. FIG. 8 is a schematic cross-sectional view illustrating a display device DD according to an embodiment.

The display device DD may include an emission area EMA and a non-emission area NEA. The display device DD may include a first bank BNK1, the alignment electrode layer ELT, the light emitting element LD, and the connection electrode layer CNE.

The emission area EMA may overlap an opening OPN defined by (or included in) the first bank BNK1 in a plan view. The light emitting elements LD may be disposed in the emission area EMA. The light emitting elements LD may not be disposed in the non-emission area NEA.

The first bank BNK1 may include (or form or provide) the opening OPN. For example, the first bank BNK1 may have a shape protruding in a thickness direction (for example, a third direction DR3 intersecting the first direction DR1 and the second direction DR2) of the base layer BSL and may surround an area of the base layer BSL in a plan view. According to an embodiment, an ink including the light emitting element LD may be supplied to the opening OPN defined by the first bank BNK1, and the light emitting element LD may be disposed in the opening OPN.

According to an embodiment, the first bank BNK1 may include an organic material such as an acrylic resin, an epoxy resin, a phenol resin, a polyamide resin, a polyimide resin, a polyimide resin, a polyester resin, a polyphenylene sulfide resin, benzocyclobutene (BCB), the like, or a combination thereof. However, the disclosure is not limited thereto.

The alignment electrode layer ELT may include electrodes for aligning the light emitting elements LD. According to an embodiment, the alignment electrode layer ELT may include a first electrode ELT1 and a second electrode ELT2. According to an embodiment, the first electrode ELT1 may be a first alignment electrode ELTA, and the second electrode ELT2 may be a second alignment electrode ELTG.

The light emitting element LD may be disposed (or aligned) on the alignment electrode layer ELT. According to an embodiment, the light emitting element LD may be aligned between the first electrode ELT1 and the second electrode ELT2 in a plan view. The light emitting elements LD may form (or configure) the light emitting unit EMU.

According to an embodiment, the first electrode ELT1 and the second electrode ELT2 may be spaced apart from each other in the first direction DR1 in the emission area EMA.

According to an embodiment, the first electrode ELT1, which is the first alignment electrode ELTA, may be an electrode to which an alternating current (AC) signal is supplied to align the light emitting elements LD. The first electrode ELT1 may be an electrode to which an anode signal is supplied so that the light emitting elements LD emit light. The second electrode ELT2, which is the second alignment electrode ELTG, may be an electrode to which a ground signal is supplied to align the light emitting elements LD. The second electrode ELT2 may be an electrode to which a cathode signal is supplied so that the light emitting elements LD emit light.

The first electrode ELT1 (or the first alignment electrode ELTA) and the second electrode ELT2 (or the second alignment electrode ELTG) may be supplied (or provided) with a first alignment signal and a second alignment signal, respectively, in a process of aligning the light emitting elements LD. For example, the ink including the light emitting element LD may be supplied (or provided) to the opening OPN, the first alignment signal may be supplied to the first electrode ELT1, and the second alignment signal may be supplied to the second electrode ELT2. The first alignment signal and the second alignment signal may have different waveforms, potentials, phases, and/or the like. For example, the first alignment signal may be an AC signal and the second alignment signal may be a ground signal. However, the disclosure is not necessarily limited thereto. An electric field may be formed between (or on) the first electrode ELT1 and the second electrode ELT2, and the light emitting elements LD may be aligned between the first electrode ELT1 and the second electrode ELT2 based on the electric field. For example, the light emitting elements LD may be moved (or rotated) by force (for example, dielectrophoresis (DEP) force) according to the electric field, and may be aligned (or disposed) on the first alignment electrode ELTA and the second alignment electrode ELTG.

The light emitting element LD may emit light based on a provided electrical signal. For example, the light emitting element LD may emit light based on a first electrical signal (for example, the anode signal) provided from a first connection electrode CNE1 and a second electrical signal (for example, the cathode signal) provided from a second connection electrode CNE2.

The first end EP1 of the light emitting element LD may be disposed adjacent to the first electrode ELT1, and the second end EP2 of the light emitting element LD may be disposed adjacent to the second electrode ELT2.

The light emitting element LD may be disposed in the opening OPN. The light emitting element LD may form (or be disposed in) the emission area EA. The emission area EA may be an area where the light emitting element LD is disposed. The emission area EA may include an area where the light emitting element LD is disposed.

The connection electrode layer CNE may be disposed on the first ends EP1 and the second ends EP2 of the light emitting elements LD. The first connection electrode CNE1 may be disposed on the first ends EP1 of the light emitting elements LD and electrically connected to the first ends EP1 of the light emitting elements LD. The second connection electrode CNE2 may be disposed on the second ends EP2 of the light emitting elements LD and electrically connected to the second ends EP2 of the light emitting elements LD. At least a portion of the first connection electrode CNE1 may overlap the first ends EP1 of the light emitting elements LD in a plan view. At least a portion of the second connection electrode CNE2 may overlap the second ends EP2 of the light emitting elements LD in a plan view.

According to an embodiment, the connection electrode layer CNE may include a first connection electrode CNE1 and a second connection electrode CNE2. The first connection electrode CNE1 may be the anode connection electrode AE, and the second connection electrode CNE2 may be the cathode connection electrode CE.

FIG. 7 schematically shows a cross-sectional structure of the display device DD focused on the pixel circuit layer PCL on which the pixel circuit PXC is formed (or disposed in) and a light-emitting-element layer EML on which the light emitting elements LD are disposed.

Referring to FIG. 7, the display device DD may include the pixel circuit layer PCL and the light-emitting-element layer EML. FIG. 7 only shows the first transistor M1 of the pixel circuits PXC for convenience of description.

The base layer BSL may provide an area in which the pixel circuit layer PCL and the light-emitting-element layer EML are disposed.

The pixel circuit layer PCL may be disposed on the base layer BSL. The pixel circuit layer PCL may include the layers (for example, BML, BFL, ACT, GI, ICL1, ILD1, ICL2, ILD2, and PSV) described above with reference to FIG. 5. For example, the pixel circuit layer PCL may include a first lower auxiliary electrode layer 1200, a second lower auxiliary electrode layer 1400, the first transistor M1, and the second power line PL2.

The first lower auxiliary electrode layer 1200 and the second lower auxiliary electrode layer 1400 may be formed by the lower auxiliary electrode layer BML. The first lower auxiliary electrode layer 1200 may be electrically connected to the first drain electrode DE1 of the first transistor M1 and may overlap a first active layer ACT1 of the first transistor M1 in a plan view. The second lower auxiliary electrode layer 1400 may be electrically connected to the second power line PL2.

The buffer layer BFL may be disposed on the base layer BSL. The buffer layer BFL may cover the lower auxiliary electrode layer BML.

The first transistor M1 may be a thin film transistor. The first transistor M1 may be electrically connected to the light emitting element LD. According to an embodiment, the first transistor M1 may include the first active layer ACT1, the first drain electrode DE1, the first source electrode SE1, and the first gate electrode GE1.

The first active layer ACT1 may be formed by the active layer ACT, and may include a first contact area contacting the first drain electrode DE1 and a second contact area contacting the first source electrode SE1.

The first gate electrode GE1 may be disposed on the gate insulating layer GI. A position of the first gate electrode GE1 may correspond to a position of a channel area of the first active layer ACT1.

The gate insulating layer GI may be disposed on the buffer layer BFL. The gate insulating layer GI may cover the first active layer ACT1.

The first interlayer insulating layer ILD1 may be disposed on the gate insulating layer GI. The first interlayer insulating layer ILD1 may cover the first gate electrode GE1 and a conductive layer 2400. The conductive layer 2400 may be formed by the first interlayer conductive layer ICL1 and may be electrically connected to the second power line PL2.

The first drain electrode DE1 and the first source electrode SE1 may be disposed on the first interlayer insulating layer ILD1. The first drain electrode DE1 may be electrically connected to the first power line PL1. The first source electrode SE1 may be electrically connected to the first electrode ELT1 through a first contact member CNP1 passing through the second interlayer insulating layer ILD2 and the protective layer PSV.

The second power line PL2 may be disposed on the first interlayer insulating layer ILD1. The second power line PL2 may be electrically connected to the second lower auxiliary electrode layer 1400, and may be electrically connected to the second electrode ELT2 through a second contact member CNP2 passing through the second interlayer insulating layer ILD2 and the protective layer PSV.

The second interlayer insulating layer ILD2 may be disposed on the first interlayer insulating layer ILD1. The second interlayer insulating layer ILD2 may cover the first drain electrode DE1, the first source electrode SE1, and the second power line PL2.

The protective layer PSV may be disposed on the second interlayer insulating layer ILD2. According to an embodiment, the protective layer PSV may be a via layer.

The light-emitting-element layer EML may be disposed on the pixel circuit layer PCL. The light-emitting-element layer EML may include first and second insulating patterns INP1 and INP2, an alignment electrode layer ELT, a first insulating layer INS1, a first bank BNK1, a light emitting element LD, a second insulating layer INS2, and a connection electrode layer CNE.

The first and second insulating patterns INP1 and INP2 may be disposed on the protective layer PSV. The first and second insulating patterns INP1 and INP2 may have various shapes. In an embodiment, the first and second insulating patterns INP1 and INP2 may protrude in a thickness direction (for example, the third direction DR3) of the base layer BSL.

The first and second insulating patterns INP1 and INP2 may form a step (e.g., a predetermined or selectable step) so that the light emitting elements LD may be readily aligned in the emission area EMA. According to an embodiment, the first and second insulating patterns INP1 and INP2 may be a partition wall (or banks). According to an embodiment, the first and second insulating patterns INP1 and INP2 may include at least one organic material and/or inorganic material. However, the disclosure is not necessarily limited thereto.

The alignment electrode layer ELT may be disposed on the protective layer PSV and/or the first and second insulating patterns INP1 and INP2. The first electrode ELT1 may receive the first alignment signal and/or first power through the first contact member CNP1. The second electrode ELT2 may receive the second alignment signal and/or second power through the second contact member CNP2.

The first insulating layer INS1 may be disposed on the alignment electrode layer ELT. For example, the first insulating layer INS1 may cover the first electrode ELT1 and the second electrode ELT2.

The first bank BNK1 may be disposed on the first insulating layer INS1. As described above, the first bank BNK1 may form a space (or an area, for example, the opening OPN of FIG. 6) in which the ink including the light emitting element LD may be accommodated.

The light emitting element LD may be disposed on the first insulating layer INS1 in an area surrounded by the first bank BNK1. According to an embodiment, the light emitting element LD may emit light based on the electrical signals (for example, the anode signal and the cathode signal) provided from the first connection electrode CNE1 and the second connection electrode CNE2.

The second insulating layer INS2 may be disposed on the light emitting element LD. The second insulating layer INS2 may cover the active layer AL of the light emitting element LD. The second insulating layer INS2 may expose at least a portion of the light emitting element LD. For example, the second insulating layer INS2 may not cover the first end EP1 and the second end EP2 of the light emitting element LD, and the first end EP1 and the second end EP2 of the light emitting element LD may be exposed and may be electrically connected to the first connection electrode CNE1 and the second connection electrode CNE2, respectively. According to an embodiment, another portion of the second insulating layer INS2 may be disposed on the first bank BNK1 and the first insulating layer INS1.

In case that the second insulating layer INS2 is formed on the light emitting elements LD after an alignment of the light emitting elements LD is completed, the light emitting elements LD may be prevented from being separated from an aligned position.

The second insulating layer INS2 may have a structure of a sing layer or multiple layers. The second insulating layer INS2 may include at least one of silicon oxide (SiOₓ), silicon nitride (SiNₓ), silicon oxynitride (SiOₓN_{y}), aluminum nitride (AlNₓ), aluminum oxide (AlₓO_{y}), zirconium oxide (ZrOₓ), hafnium oxide (HfOₓ), and titanium oxide (TiOₓ). However, the disclosure is not limited thereto.

The first connection electrode CNE1 and the second connection electrode CNE2 may be disposed on the first insulation layer INS1 and the second insulation layer INS2. The first connection electrode CNE1 may be electrically connected to the first end EP1 of the light emitting element LD. The second connection electrode CNE2 may be electrically connected to the second end EP2 of the light emitting element LD.

The first connection electrode CNE1 may be electrically connected to the first electrode ELT1 through a first contact portion CNT1 passing through the first insulating layer INS1 and the second insulating layer INS2, and the second connection electrode CNE2 may be electrically connected to the second electrode ELT2 through a second contact portion CNT2 passing through the first insulating layer INS1 and the second insulating layer INS2. According to an embodiment, the first connection electrode CNE1 may be directly electrically connected to a line (for example, one of the base lines BPL of FIG. 5) of the pixel circuit layer PCL through the first contact portion CNT1. The second connection electrode CNE2 may be directly electrically connected to a line of the pixel circuit layer PCL through the second contact portion CNT2.

According to an embodiment, the first connection electrode CNE1 and the second connection electrode CNE2 may be patterned at the same time in a same process. However, the disclosure is not necessarily limited thereto. After one of the first connection electrode CNE1 and the second connection electrode CNE2 is patterned, another one of the first connection electrode CNE1 and the second connection electrode CNE2 may be patterned.

FIG. 8 schematically shows a cross-sectional structure of the display device DD focused on configurations disposed on the light-emitting-element layer EML.

Referring to FIG. 8, sub-pixel areas SPXA each corresponding to the sub-pixels SPX may be formed in the display area DA. The sub-pixel areas SPXA may include a first sub-pixel area SPXA1 corresponding to the first sub-pixel SPX1, a second sub-pixel area SPXA2 corresponding to the second sub-pixel SPX2, and a third sub-pixel area SPXA3 corresponding to the third sub-pixel SPX3. The first sub-pixel area SPXA1, the second sub-pixel area SPXA2, and the third sub-pixel area SPXA3 may be arranged in the first direction DR1.

A second bank BNK2 may be disposed between or at a boundary between the first to third sub-pixel areas SPXA1, SPXA2, and SPXA3, and may define (or form) a space (or an area) overlapping each of the first to third sub-pixel areas SPXA1, SPXA2, and SPXA3 in a plan view. The space defined by (or formed by) the second bank BNK2 may be an area where a color conversion layer CCL may be disposed.

The second bank BNK2 may surround an area of the light-emitting-element layer EML in a plan view. The second bank BNK2 may protrude in the thickness direction (for example, the third direction DR3) of the base layer BSL, and the second bank BNK2 may define (or form) a space (or an area). A space where the color conversion layer CCL is disposed may be formed in the opening OPN.

The second bank BNK2 may include an organic material such as an acrylic resin, an epoxy resin, a phenol resin, a polyamide resin, a polyimide resin, a polyester resin, a polyphenylene sulfide resin, benzocyclobutene, the like, or a combination thereof. However, the disclosure is not necessarily limited thereto.

The color conversion layer CCL may be disposed on the light emitting elements LD in the space surrounded by the second bank BNK2 in a plan view (or between adjacent ones of the second bank BNK2). The color conversion layer CCL may include a first color conversion layer CCL1 disposed in the first sub-pixel SPX1, a second color conversion layer CCL2 disposed in the second sub-pixel SPX2, and a scattering layer LSL disposed in the third sub-pixel SPX3.

The color conversion layer CCL may be disposed on the light emitting element LD. The color conversion layer CCL may change a wavelength of light. According to an embodiment, each of the first to third sub-pixels SPX1, SPX2, and SPX3 may include light emitting elements LD emitting light of a same color. For example, the first to third sub-pixels SPX1, SPX2, and SPX3 may include light emitting elements LD emitting light of a third color (or blue). As the color conversion layer CCL including color conversion particles is disposed in each of the first to third sub-pixels SPX1, SPX2, and SPX3, a full color image may be displayed.

The first color conversion layer CCL1 may include first color conversion particles that convert the light of the third color emitted from the light emitting element LD into light of a first color. For example, the first color conversion layer CCL1 may include multiple first quantum dots QD1 dispersed in a matrix material such as a base resin or the like.

According to an embodiment, in case that the light emitting element LD is a blue light emitting element emitting blue light and the first sub-pixel SPX1 is a red pixel, the first color conversion layer CCL1 may include a first quantum dot QD1 converting the blue light emitted from the blue light emitting element into red light. The first quantum dot QD1 may absorb the blue light and emit the red light by shifting a wavelength according to an energy transition. In case that the first sub-pixel SPX1 is a pixel of another color, the first color conversion layer CCL1 may include a first quantum dot QD1 corresponding to the another color of the first sub-pixel SPX1.

The second color conversion layer CCL2 may include second color conversion particles that convert the light of the third color emitted from the light emitting element LD into light of a second color. For example, the second color conversion layer CCL2 may include multiple second quantum dots QD2 dispersed in a matrix material such as a base resin or the like.

According to an embodiment, in case that the light emitting element LD is the blue light emitting element emitting the blue light and the second sub-pixel SPX2 is a green pixel, the second color conversion layer CCL2 may include a second quantum dot QD2 converting the blue light emitted from the blue light emitting element into green light. The second quantum dot QD2 may absorb the blue light and emit the green light by shifting a wavelength according to an energy transition. In case that the second sub-pixel SPX2 is a pixel of another color, the second color conversion layer CCL2 may include a second quantum dot QD2 corresponding to the another color of the second sub-pixel SPX2.

According to an embodiment, as the blue light having a relatively short wavelength in a visible ray area is incident to each of the first quantum dot QD1 and the second quantum dot QD2, an absorption coefficient of the first quantum dot QD1 and the second quantum dot QD2 may increase. Accordingly, efficiency of light emitted from the first sub-pixel SPX1 and the second sub-pixel SPX2 may be improved, and excellent color reproducibility may be secured. Since the light emitting unit EMU of the first to third sub-pixels SPX1, SPX2, and SPX3 is configured with the light emitting elements LD of the same color (for example, the blue light emitting element), manufacturing efficiency of the display device DD may be increased.

The scattering layer LSL may be provided to efficiently use the light of the third color (or blue) emitted from the light emitting element LD. For example, in case that the light emitting element LD is the blue light emitting element emitting the blue light and the third sub-pixel SPX3 is a blue pixel, the scattering layer LSL may include at least one type of scattering body SCT in order to efficiently use the light emitted from the light emitting element LD. For example, the scattering body SCT of the scattering layer LSL may include light scattering particles or a light scattering material. For example, the scattering body may include at least one of silica (SiOₓ) (for example, silica bead, hollow silica, and the like), titanium oxide (TiOₓ), zirconium oxide (ZrOₓ), aluminum oxide (AlₓO_{y}), indium oxide (InₓO_{y}), zinc oxide (ZnOₓ), tin oxide (SnOₓ), and antimony oxide (SbₓO_{y}). However, the disclosure is not limited thereto. The scattering body SCT may be disposed in the third sub-pixel SPX3, and may be selectively included in (or disposed in) the first color conversion layer CCL1 or the second color conversion layer CCL2. According to an embodiment, the scattering layer LSL including a transparent polymer or the like may be disposed in the third sub-pixel SPC3, and the scattering body SCT may be omitted.

A first capping layer CPL1 may be disposed on the color conversion layer CCL and the second bank BNK2. The first capping layer CPL1 may be disposed in the first to third sub-pixels SPX1, SPX2, and SPX3. The first capping layer CPL1 may cover the color conversion layer CCL. The first capping layer CPL1 may prevent damage or contamination of the color conversion layer CCL due to permeation of an impurity such as moisture, air, or the like from an outside.

The first capping layer CPL1 may be an inorganic layer, and may include at least one of silicon nitride (SiNₓ), aluminum nitride (AlNₓ), titanium nitride (TiNₓ), silicon oxide (SiOₓ), aluminum oxide (AlₓO_{y}), titanium oxide (TiOₓ), silicon oxycarbide (SiOₓC_{y}), and silicon oxynitride (SiOₓN_{y}).

An optical layer OPL may be disposed on the first capping layer CPL1. The optical layer OPL may improve light efficiency by recycling light provided from the color conversion layer CCL by total reflection. In an embodiment, the optical layer OPL may have a relatively low refractive index compared to the color conversion layer CCL.

A second capping layer CPL2 may be disposed on the optical layer OPL. The second capping layer CPL2 may be disposed in the first to third sub-pixels SPX1, SPX2 and SPX3. The second capping layer CPL2 may cover the optical layer OPL. The second capping layer CPL2 may prevent damage or contamination of the optical layer OPL due to permeation of an impurity such as moisture, air, or the like from the outside.

The second capping layer CPL2 may be an inorganic layer, and may include at least one of silicon nitride (SiNₓ), aluminum nitride (AlNₓ), titanium nitride (TiNₓ), silicon oxide (SiOₓ), aluminum oxide (AlₓO_{y}), titanium oxide (TiOₓ), silicon oxycarbide (SiOₓC_{y}), and silicon oxynitride (SiOₓN_{y}).

A planarization layer PLL may be disposed on the second capping layer CPL2. The planarization layer PLL may be disposed in the first to third sub-pixels SPX1, SPX2, and SPX3.

The planarization layer PLL may include an organic material such as an acrylic resin, an epoxy resin, a phenol resin, a polyamide resin, a polyimide resin, a polyester resin, a polyphenylene sulfide resin, benzocyclobutene, the like, or a combination thereof. However, the disclosure is not necessarily limited thereto, and the planarization layer PLL may include various types of inorganic materials such as silicon oxide (SiOₓ), silicon nitride (SiNₓ), silicon oxynitride (SiOₓN_{y}), aluminum nitride (AlNₓ), aluminum oxide (AlₓO_{y}), zirconium oxide (ZrOₓ), hafnium oxide (HfOₓ), titanium oxide (TiOₓ), the like, or a combination thereof.

A color filter layer CFL may be disposed on the planarization layer PLL. The color filter layer CFL may include color filters CF1, CF2, and CF3 corresponding to the color of each of the first to third sub-pixels SPX1, SPX2, and SPX3. Since the color filters CF1, CF2, and CF3 corresponding to the colors of each of the first to third sub-pixels SPX1, SPX2, and SPX3 are disposed, a full color image may be displayed.

The color filter layer CFL may include a first color filter CF1 disposed in the first sub-pixel SPX1 to selectively transmit light emitted from the first sub-pixel SPX1, a second color filter CF2 disposed in the second sub-pixel SPX2 to selectively transmit light emitted from the second sub-pixel SPX2, and a third color filter CF3 disposed in the third sub-pixel SPX3 to selectively transmit light emitted from the third sub-pixel SPX3.

According to an embodiment, the first color filter CF1, the second color filter CF2, and the third color filter CF3 may be a red color filter, a green color filter, and a blue color filter, respectively, but the disclosure is not necessarily limited thereto. Hereinafter, when referring to an arbitrary color filter among the first color filter CF1, the second color filter CF2, and the third color filter CF3, or comprehensively referring to two or more types of color filters CF1, CF2, and CF3, the arbitrary color filter or the color filters are referred to as a “color filter” or “color filters”.

The first color filter CF1 may overlap the first color conversion layer CCL1 in a plan view (or in the thickness direction (for example, the third direction DR3) of the base layer BSL). The first color filter CF1 may include a color filter material that selectively transmits the light of the first color (or red). For example, in case that the first sub-pixel SPX1 is a red pixel, the first color filter CF1 may include a red color filter material.

The second color filter CF2 may overlap the second color conversion layer CCL2 in a plan view (or in the thickness direction (for example, the third direction DR3) of the base layer BSL). The second color filter CF2 may include a color filter material that selectively transmits the light of the second color (or green). For example, in case that the second sub-pixel SPX2 is a green pixel, the second color filter CF2 may include a green color filter material.

The third color filter CF3 may overlap the scattering layer LSL in a plan view (or in the thickness direction (for example, the third direction DR3) of the base layer BSL). The third color filter CF3 may include a color filter material that selectively transmits the light of the third color (or blue). For example, in case that the third sub-pixel SPX3 is a blue pixel, the third color filter CF3 may include a blue color filter material.

According to an embodiment, a light blocking layer BM may be disposed between the first to third color filters CF1, CF2, and CF3. As described above, in case that the light blocking layer BM is formed between the first to third color filters CF1, CF2, and CF3, a color mixing defect viewed from a front surface or a side surface of the display device DD may be prevented. A material of the light blocking layer BM is not particularly limited, and the light blocking layer BM may include various light absorbing materials. For example, the light blocking layer BM may include a black matrix or the like, or the first to third color filters CF1, CF2, and CF3 may be stacked on each other to implement the light blocking layer BM.

An overcoat layer OC may be disposed on the color filter layer CFL. The overcoat layer OC may be disposed in the first to third sub-pixels SPX1, SPX2, and SPX3. The overcoat layer OC may cover lower members (for example, CFL, BM, PLL, CPL2, OPL, CPL1, and the like) including the color filter layer CFL. The overcoat layer OC may prevent permeation of moisture or air into the above-described lower member. The overcoat layer OC may protect the above-described lower member from a foreign substance such as dust or the like.

The overcoat layer OC may include an organic material such as an acrylic resin, an epoxy resin, a phenol resin, a polyamide resin, a polyimide resin, a polyester resin, a polyphenylene sulfide resin, benzocyclobutene, the like, or a combination thereof. However, the disclosure is not necessarily limited thereto, and the overcoat layer OC may include various types of inorganic materials such as silicon oxide (SiOₓ), silicon nitride (SiNₓ), silicon oxynitride (SiOₓN_{y}), aluminum nitride (AlNₓ), aluminum oxide (AlₓO_{y}), zirconium oxide (ZrOₓ), hafnium oxide (HfOₓ), titanium oxide (TiOₓ), the like, or a combination thereof.

An outer film layer OFL may be disposed on the overcoat layer OC. The outer film layer OFL may be disposed on the display device DD to reduce an external influence. The outer film layer OFL may be disposed in the first to third sub-pixels SPX1, SPX2, and SPX3. According to an embodiment, the outer film layer OFL may include one of a polyethylene terephthalate (PET) film, a low reflection film, a polarizing film, and a transmittance controllable film, but the disclosure is not necessarily limited thereto. According to an embodiment, the sub-pixels SPX1, SPX2, and SPX3 may include an upper substrate other than the outer film layer OFL.

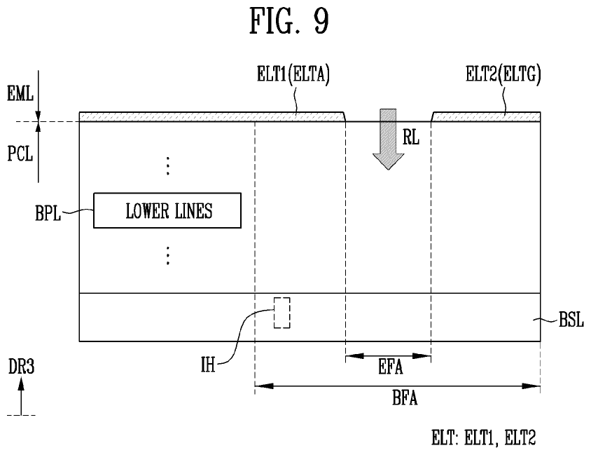

A structure of the display device DD including the inner hole IH is described in more detail with reference to FIGS. 9 to 17. The above-described element is briefly described or is not repeated.

FIGS. 9 to 17 are schematic diagrams illustrating a structure of the display device DD including the inner hole IH according to an embodiment.

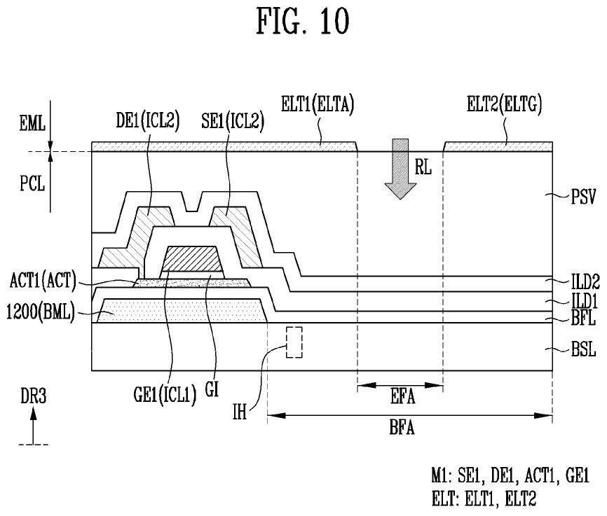

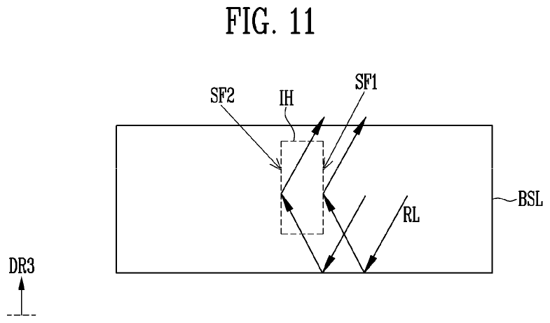

FIGS. 9 to 11 are a schematic cross-sectional view illustrating a structure of the display device DD including the inner hole IH according to an embodiment. FIGS. 9 and 10 are schematic cross-sectional views illustrating an arrangement of the inner hole IH, the lower lines BPL, and the alignment electrode layer ELT. FIG. 9 schematically shows configurations of the pixel circuit layer PCL and the light-emitting-element layer EML on the base layer BSL. FIG. 10 schematically shows configurations of the light-emitting-element layer EML, and shows a circuit element and lines in the pixel circuit layer PCL according to an embodiment. FIG. 11 schematically shows a light reflection pattern in an area adjacent to the inner hole IH in the base layer BSL.

Referring to FIGS. 9 to 11, the lower lines BPL may be disposed (or patterned) in an area of the pixel circuit layer PCL. For example, at least one of the lower auxiliary electrode layers BML, the first interlayer conductive layer ICL1, and the second interlayer conductive layer ICL2 may be disposed in an area of the pixel circuit layer PCL.

The lower lines BPL may be disposed only in some areas, and the pixel circuit layer PCL may include a line-free area BFA in which the lower lines BPL are not disposed. For example, the line-free area BFA may not overlap the lower lines BPL in a plan view. In the line-free area BFA, insulating layer(s) (for example, at least one of the buffer layer BFL, the gate insulating layer GI, the first interlayer insulating layer ILD1, the second interlayer insulating layer ILD2, and the protective layer PSV) may be disposed on the base layer BSL in the pixel circuit layer PCL. According to an embodiment, an electrode, a semiconductor structure, or the like for forming the first transistor M1 may be disposed in an area other than the line-free area BFA. According to an embodiment, the first lower auxiliary electrode layer 1200 may be disposed in the area other than the line-free area BFA.

The alignment electrode layer ELT may be disposed (or patterned) in an area of the light-emitting-element layer EML. The alignment electrode layer ELT may expose at least a portion of a surface of the pixel circuit layer PCL. For example, the first alignment electrode ELTA (or the first electrode ELT1) or the second alignment electrode ELTG (or the second electrode ELT2) may be disposed in a partial area of the pixel circuit layer PCL.

The first alignment electrode ELTA and the second alignment electrode ELTG may be disposed only in a partial area to form an electrode-free area EFA. For example, the electrode-free area EFA may be an area defined by a space between the first alignment electrode ELTA and the second alignment electrode ELTG apart from each other. According to an embodiment, the electrode-free area EFA may be entirely covered by the line-free area BFA in a plan view. For example, the electrode-free area EFA may be entirely included in the line-free area BFA in a plan view.

The electrode-free area EFA may overlap the light emitting elements LD in a plan view. The light emitting elements LD may be disposed in the electrode-free area EFA. For example, the electrode-free area EFA may correspond to an alignment area in which the light emitting elements LD are arranged between the first alignment electrode ELTA and the second alignment electrode ELTG.

The electrode-free area EFA may not overlap the lower lines BPL in a plan view. The electrode-free area EFA may overlap the line-free area BFA in a plan view.

According to an embodiment, the light emitting elements LD may be aligned based on the electric field formed between the first alignment electrode ELTA and the second alignment electrode ELTG. Experimentally, in case that the lower lines BPL are formed in an area between the first alignment electrode ELTA and the second alignment electrode ELTG, the formed electric fields may be interfered with by the lower lines BPL, and a concern that an alignment degree of the light emitting elements LD and reliability for the alignment degree are damaged may exist. However, according to an embodiment, since the electrode-free area EFA corresponding to an alignment area in which the light emitting elements LD are arranged may overlap the line-free area BFA in which the lower lines BPL are not formed in a plan view, a risk that the alignment degree of the light emitting elements LD and the reliability for the alignment degree are damaged may be substantially prevented. The electrode-free area EFA corresponding to the alignment area in which the light emitting elements LD are arranged may be disposed in the line-free area BFA in which the lower lines BPL are not formed. For example, an influence of the electrical signals (for example, the electric field and the like) for aligning the light emitting elements LD may be reduced, and the alignment degree of the light emitting elements LD may be substantially improved.

According to an embodiment, the inner hole IH may be formed in the base layer BSL. For example, the inner hole IH may include (or form) an air-pocket formed inside the base layer BSL. For example, during a process for manufacturing the display device DD, a laser may be applied to the base layer BSL, and at least a portion of an inside of the base layer BSL may be removed to form the inner hole IH. Since the inner hole IH may include the air-pocket, an internal structure of the base layer BSL adjacent to the inner hole IH may form an interface.

The inner hole IH may be disposed between the lower lines BPL and the electrode-free area EFA in a plan view. The inner hole IH may be disposed between the lower lines BPL and the light emitting element LD in a plan view.

According to an embodiment, some of light emitted from the light emitting element LD may be provided as a rear surface light RL. For example, the rear surface light RL may be transmitted to a lower portion through the electrode-free area EFA.

Since the inner hole IH may be disposed between the lower lines BPL and the electrode-free area EFA in a plan view, the rear surface light RL may be prevented from being applied to at least a portion of the lower lines BPL. For example, since the inner hole IH may be disposed between the first transistor M1 and the electrode-free area EFA in a plan view, a risk that the rear surface light RL is applied to at least a portion (for example, the first active layer ACT1) of the first transistor M1 may be prevented.

For example, the inner hole IH may reflect at least a portion of the rear surface light RL to prevent the rear surface light RL from being transmitted to the circuit element of the pixel circuit PXC. According to an embodiment, the inner hole IH may form a first interface SF1 and a second interface SF2 with the internal structure of the base layer BSL. According to an embodiment, the rear surface light RL may be totally reflected at the first interface SF1. For example, since the inner hole IH may include the air-pocket, the rear surface light RL may be transmitted from the base layer BSL having a relatively high refractive index at the first interface SF1 to the inner hole IH having a relatively low refractive index. Accordingly, the rear surface light RL may be totally reflected and may not be transmitted to the first transistor M1. At least a portion of the rear surface light RL may be reflected at the second interface SF2. For example, the second interface SF2 may be a boundary where different materials are adjacent to each other, and at least a portion of light applied to the second interface SF2 may be reflected.

Since the inner hole IH may be formed in the internal structure of the base layer BSL, a structure for controlling a light path may be provided. Furthermore, since an arrangement of the inner hole IH is determined based on the electrode-free area EFA and the first transistor M1, a risk that light is applied to the circuit element forming the pixel circuit PXC may be prevented. Experimentally, in case that light is applied to the circuit element forming the pixel circuit PXC, reliability of an electrical signal may be damaged, such as a shift of a threshold-voltage of the transistors M1, M2, and M3 or the like, and the embodiment of the disclosure may reduce such a risk.

The inner hole IH may be disposed in the line-free area BFA. For example, the inner hole IH may not overlap the lower lines BPL in a plan view. Since the inner hole IH may be disposed so as not to overlap the lower lines BPL in a plan view, a risk that structural stability of the pixel circuit layer PCL is damaged due to the inner hole IH may not occur. However, the disclosure does not exclude all structures in which the inner hole IH overlaps a portion of the lower lines BPL in a plan view. For example, a portion equal to or greater than a half of the inner hole IH may not overlap the lower lines BPL in a plan view, and a portion equal to or less than a half of the inner hole IH may overlap the lower lines BPL in a plan view.

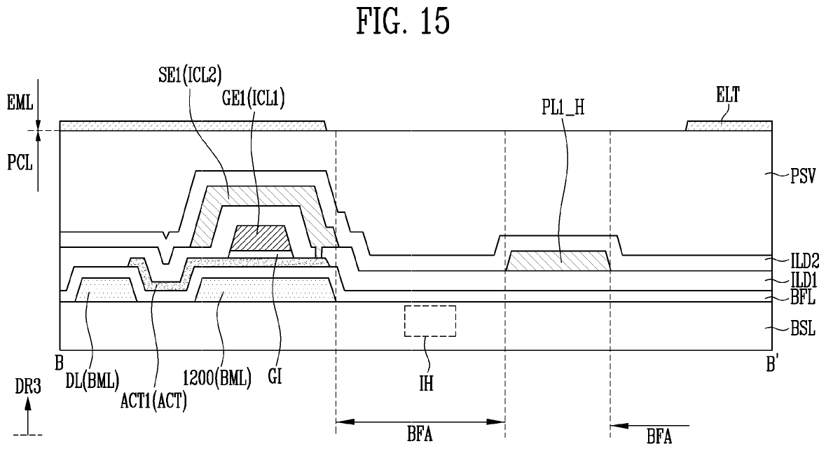

FIGS. 12 to 15 show an arrangement of the lower lines BPL and the inner hole IH in more detail. FIGS. 12 to 14 are schematic plan views illustrating a structure of a display device DD including the inner hole IH according to an embodiment. FIG. 15 is a schematic cross-sectional view illustrating a structure of the display device DD including the inner hole IH according to an embodiment. FIG. 15 is a schematic cross-sectional view taken along line B-B′ of FIG. 12.

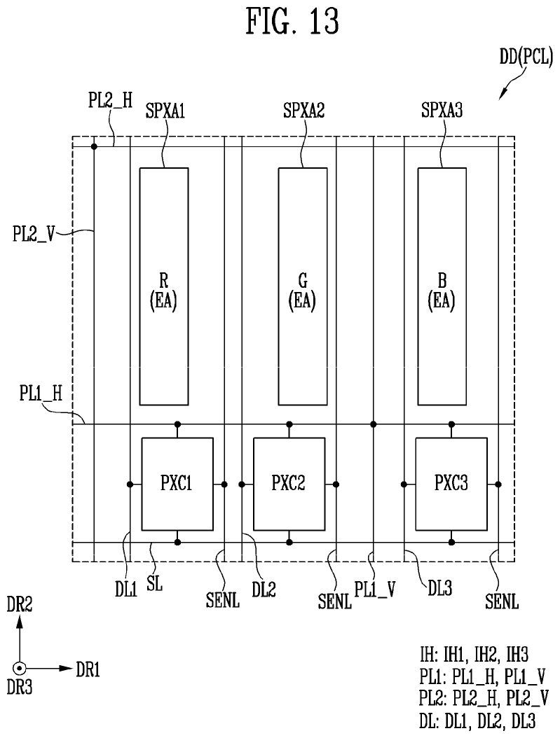

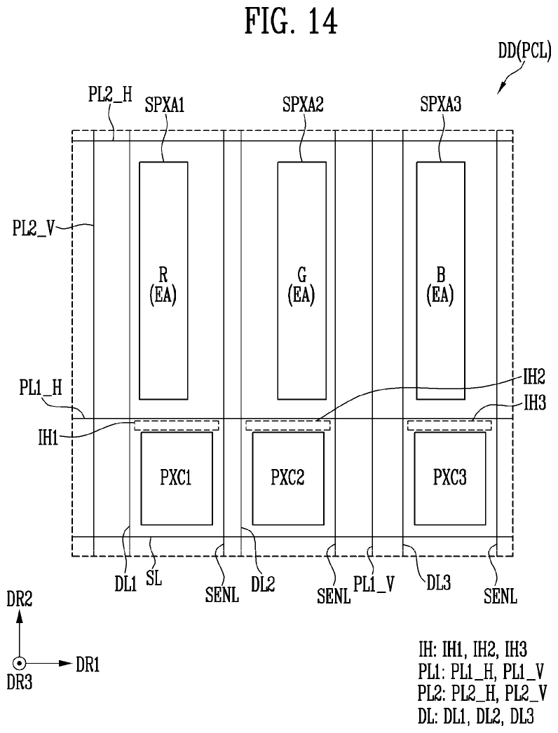

FIGS. 12 to 14 are schematic plan views illustrating an electrode structure of the display device DD according to an embodiment. FIGS. 12 to 14 may be schematic views showing a structure of the lower lines BPL. FIG. 12 may be a schematic view illustrating a planar structure of electrodes (of the pixel circuit layer PCL) based on the electrode patterns (the layers (for example, BSL, BML, BFL, ACT, GI, ICL1, ILD1, ICL2, ILD2, PSV, ELT, and CNE) expressed by the same hatching) described above with reference to FIG. 5. FIGS. 13 and 14 are schematic plan views illustrating an area corresponding to FIG. 12, and may be plan views schematically illustrates an electrode structure of the display device DD according to an embodiment.

FIG. 12 shows the lower auxiliary electrode layer BML, the active layer ACT, the first interlayer conductive layer ICL1, and the second interlayer conductive layer ICL2. In FIG. 12, the lower auxiliary electrode layer BML, the first interlayer conductive layer ICL1, and the second interlayer conductive layer ICL2 are shown in the same patterning as the patterning shown in FIG. 5, and the active layer ACT is shown as a relatively dark outline without a patterning so that layers may be clearly distinguished.

In FIG. 12, contact holes (for example, CNP of FIG. 12) for electrically connecting different patterns (for example, the lower auxiliary electrode layer BML, the active layer ACT, the first interlayer conductive layer ICL1, and the second interlayer conductive layer ICL2) are shown with an X in a quadrangular shape. In FIG. 12, an embodiment in which the scan line SL and the scan control line SSL are integrated is shown.

Referring to FIGS. 12 to 15, the lower lines BPL for forming (or included in) the pixel circuit layer PCL may be disposed (or patterned) in an area, and the pixel circuits PXC and lines connected to the pixel circuits PXC may be formed.

The pixel circuit PXC may include a first pixel circuit PXC1, a second pixel circuit PXC2, and a third pixel circuit PXC3. Each of the first pixel circuit PXC1, the second pixel circuit PXC2, and the third pixel circuit PXC3 may include the first transistor M1, the second transistor M2, the third transistor M3, and the storage capacitor CST. The first pixel circuit PXC1, the second pixel circuit PXC2, and the third pixel circuit PXC3 may be spaced apart from each other in the first direction DR1. Each of the first pixel circuit PXC1, the second pixel circuit PXC2, and the third pixel circuit PXC3 may be the pixel circuit PXC for each of the sub-pixels SPX. For example, the first pixel circuit PXC1 may correspond to the first sub-pixel SPX1, the second pixel circuit PXC2 may correspond to the second sub-pixel SPX2, and the third pixel circuit PXC3 may correspond to the third sub-pixel SPX3.

According to an embodiment, the first transistor M1 of each of the first pixel circuit PXC1, the second pixel circuit PXC2, and the third pixel circuit PXC3 may include a first source electrode SE1, a first gate electrode GE1, a first drain electrode DE1, and a first active layer ACT1. According to an embodiment, the second transistor M2 of each of the first pixel circuit PXC1, the second pixel circuit PXC2, and the third pixel circuit PXC3 may include a second source electrode SE2, a second gate electrode GE2, a second drain electrode DE2, and a second active layer ACT2. According to an embodiment, the third transistor M3 of each of the first pixel circuit PXC1, the second pixel circuit PXC2, and the third pixel circuit PXC3 may include a third source electrode SE3, a third gate electrode GE3, a third drain electrode DE3, and a third active layer ACT3.

The storage capacitor CST may include an upper electrode UE and a lower electrode LE. According to an embodiment, the storage capacitor CST may include a first storage capacitor CST1 included in the first pixel circuit PXC1, a second storage capacitor CST2 included in the second pixel circuit PXC2, and a third storage capacitor CST3 included in the third pixel circuit PXC3. According to an embodiment, each of the upper electrode UE and the lower electrode LE may be at least one of the lower auxiliary electrode layer BML, the first interlayer conductive layer ICL1, and the second interlayer conductive layer ICL2.

The scan line SL may extend in the first direction DR1. The scan line SL may be formed by the lower auxiliary electrode layer BML. According to an embodiment, the scan line SL and the scan control line SSL may be integral with each other.

The data lines DL may extend in the second direction DR2. The data lines DL may be spaced apart from each other in the first direction DR1. The data lines DL may include a first data line DL1, a second data line DL2, and a third data line DL3. The first data line DL1 may be a data line for the first pixel circuit PXC1 and may be electrically connected to the second drain electrode DE2 of the second transistor M2 of the first pixel circuit PXC1. The second data line DL2 may be a data line for the second pixel circuit PXC2 and may be electrically connected to the second drain electrode DE2 of the second transistor M2 of the second pixel circuit PXC2. The third data line DL3 may be a data line for the third pixel circuit PXC3 and may be electrically connected to the second drain electrode DE2 of the second transistor M2 of the third pixel circuit PXC3.

The sensing line SENL may extend in the second direction DR2. The sensing line SENL may be electrically connected to the third drain electrode DE3 of the third transistor M3 of the first to third pixel circuits PXC1, PXC2, and PXC3. The sensing line SENL may be formed by the lower auxiliary electrode layer BML.

The first power line PL1 may include a first-first power line PL1_H extending in the first direction DR1 and a first-second power line PL1_V extending in the second direction DR2. The first-first power line PL1_H and the first-second power line PL1_V may be electrically connected to each other through a contact hole. Accordingly, the first power line PL1 may be formed in a mesh structure and may be electrically connected to the first drain electrode DE1 of the first transistor M1 of the first to third pixel circuits PXC1, PXC2, and PXC3.

According to an embodiment, the first-second power line PL1_V may overlap the sub-pixel areas SPXA in a plan view in the first direction DR1. For example, the first-second power line PL1_V may extend between the sub-pixel areas SPXA in the second direction DR2. According to an embodiment, at least a portion of the first-second power line PL1_V may be disposed between the second sub-pixel area SPXA2 and the third sub-pixel area SPXA3.

The second power line PL2 may include a second-first power line PL2_H extending in the first direction DR1 and a second-second power line PL2_V extending in the second direction DR2. The second-first power line PL2_H and the second-second power line PL2_V may be electrically connected to each other through a contact hole. Accordingly, the second power line PL2 may be formed in a mesh structure and may be electrically connected to the second electrode ELT2 (for example, the second alignment electrode ELTG) (or the second connection electrode CNE2).

The emission area EA may be formed so as not to overlap the lower lines BPL in a plan view. For example, the light emitting elements LD may be disposed so as not to overlap the lower lines BPL in a plan view.

The emission area EA may include a first emission area R, a second emission area G, and a third emission area B. The first emission area R may be an area where the light emitting elements LD for forming the first sub-pixel SPX1 are disposed. The first emission area R may overlap the first sub-pixel area SPXA1 in a plan view. The first sub-pixel area SPXA1 may be disposed in the first emission area R. The second emission area G may be an area where the light emitting elements LD for forming the second sub-pixel SPX2 are disposed. The second emission area G may overlap the second sub-pixel area SPXA2 in a plan view. The second sub-pixel area SPXA2 may be disposed in the second emission area G. The third emission area B may be an area where the light emitting elements LD for forming the third sub-pixel SPX3 are disposed. The third emission area B may overlap the third sub-pixel area SPXA3 in a plan view. The third sub-pixel area SPXA3 may be disposed in the third emission area B.

The emission area EA may not overlap the lower lines BPL in a plan view. The lower lines BPL may not be disposed in the emission area EA. The first emission area R, the second emission area G, and the third emission area B may be disposed in an area where the lower lines BPL are not disposed in a plan view. According to an embodiment, the first emission area R may be disposed between the first data line DL1 and the sensing line SENL of the first pixel circuit PXC1 in a plan view. The second emission area G may be disposed between the second data line DL2 and the sensing line SENL of the second pixel circuit PXC2 in a plan view. The third emission area B may be disposed between the third data line DL3 and the sensing line SENL of the third pixel circuit PXC3 in a plan view.

According to an embodiment, the inner hole IH may include one or more inner holes IH1, IH2, and IH3 spaced apart from each other in the first direction DR1. For example, the inner hole IH may include a first inner hole IH1, a second inner hole IH2, and a third inner hole IH3. According to an embodiment, the first inner hole IH1, the second inner hole IH2, and the third inner hole IH3 may be sequentially disposed in a direction in which the first to third pixel circuits PXC1, PXC2, and PXC3 are sequentially disposed (for example, in the first direction DR1).

The inner hole IH may be disposed between the pixel circuit PXC and the emission area EA. For example, the inner hole IH may be disposed between the first transistor M1 and the emission area EA. The first inner hole IH1 may be disposed between the first transistor M1 of the first pixel circuit PXC1 and the first emission area R. The second inner hole IH2 may be disposed between the first transistor M1 of the second pixel circuit PXC2 and the second emission area G. The third inner hole IH3 may be disposed between the first transistor M1 of the third pixel circuit PXC3 and the third emission area B.

The inner hole IH may be disposed between the emission area EA and the pixel circuit PXC in the second direction DR2 in a plan view. For example, the first inner hole IH1 may be disposed between the first emission area R and the first pixel circuit PXC1 in the second direction DR2 in a plan view. The second inner hole IH2 may be disposed between the second emission area G and the second pixel circuit PXC2 in the second direction DR2 in a plan view. The third inner hole IH3 may be disposed between the third emission area B and the third pixel circuit PXC3 in the second direction DR2 in a plan view.

The inner hole IH may not overlap the emission area EA and the pixel circuit PXC in the first direction DR1 in a plan view. For example, the first inner hole IH1 may not overlap the first emission area R and the first pixel circuit PXC1 in the first direction DR1 in a plan view. The second inner hole IH2 may not overlap the second emission area G and the second pixel circuit PXC2 in the first direction DR1 in a plan view. The third inner hole IH3 may not overlap the third emission area B and the third pixel circuit PXC3 in the first direction DR1 in a plan view.

According to the above-described arrangement of the inner hole IH, the inner hole IH may effectively block the rear surface light RL applied from the emission area EA.

According to an embodiment, the inner hole IH may be disposed between the first-first power line PL1_H and the first transistor M1. For example, the inner hole IH may be disposed between the first source electrode SE1 of the first transistor M1 and the first-first power line PL1_H in a plan view. The inner hole IH may be disposed between the first lower auxiliary electrode layer 1200 and the first-first power line PL1_H in a plan view. Accordingly, the inner hole IH may be disposed in the line-free area BFA in which the lower lines BPL are not disposed.

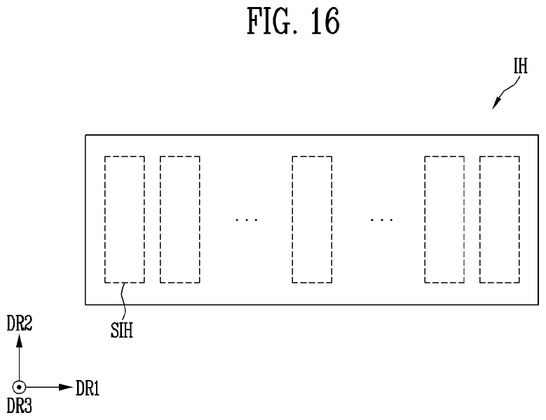

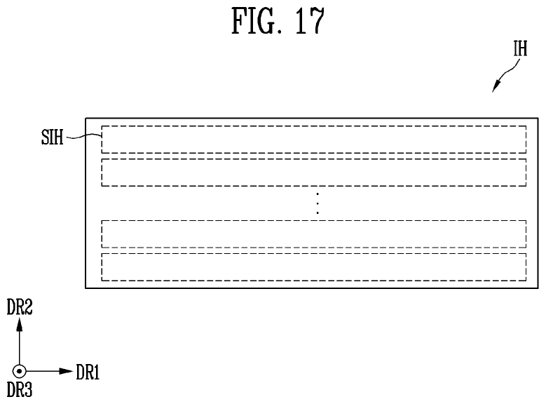

In FIGS. 16 and 17, an embodiment in which the inner hole IH includes a sub-inner hole SIH is described. FIGS. 16 and 17 are schematic plan views illustrating a structure of the display device DD including an inner hole IH according to an embodiment. FIGS. 16 and 17 are schematic plan views illustrating the inner hole IH.

The inner hole IH may have a single hole structure, or may have a multiple hole structure including two or more sub-inner holes SIH according to an embodiment.

In case that the sub-inner holes SIH are spaced apart from each other in the first or second directions DR1 or DR2, since the air-pocket in the base layer BSL may not be disposed on an excessively wide area, structural stability of the pixel circuit layer PCL may be improved.

According to an embodiment of FIG. 16, the inner hole IH may include two or more sub-inner holes SIH sequentially disposed in the first direction DR1. Since the sub-inner holes SIH may be sequentially disposed in a direction the inner hole IH extends, process convenience may be improved.

In another embodiment, referring to FIG. 17, the inner hole IH may include two or more sub-inner holes SIH sequentially disposed in the second direction DR2. The sub-inner hole SIH may form a large number of interfaces SF1 and SF2 (see, e.g., FIG. 11) in the second direction DR2. Since the rear surface light RL may be transmitted in a direction parallel to the second direction DR2 (for example, vertical direction in FIG. 17), light reflection efficiency of the inner hole IH may be further improved.

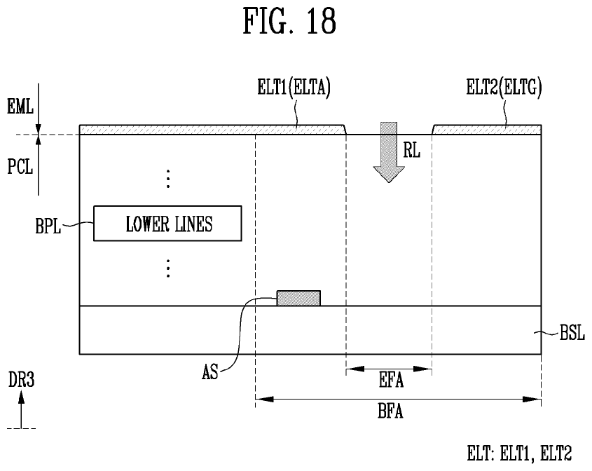

A display device DD according to another embodiment is described with reference to FIGS. 18 to 20. A content that may overlap the above-described content is briefly described or is not repeated.

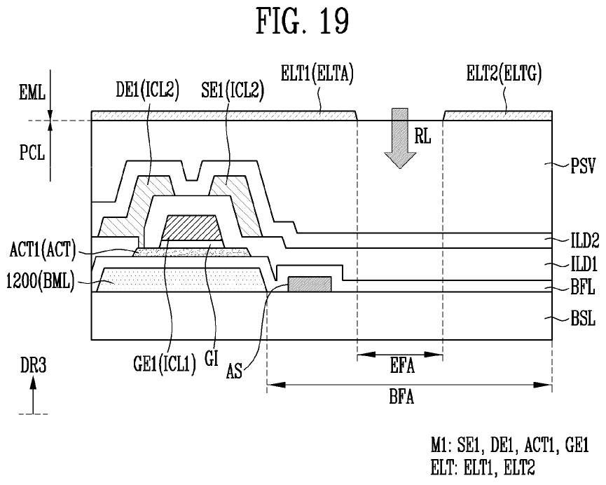

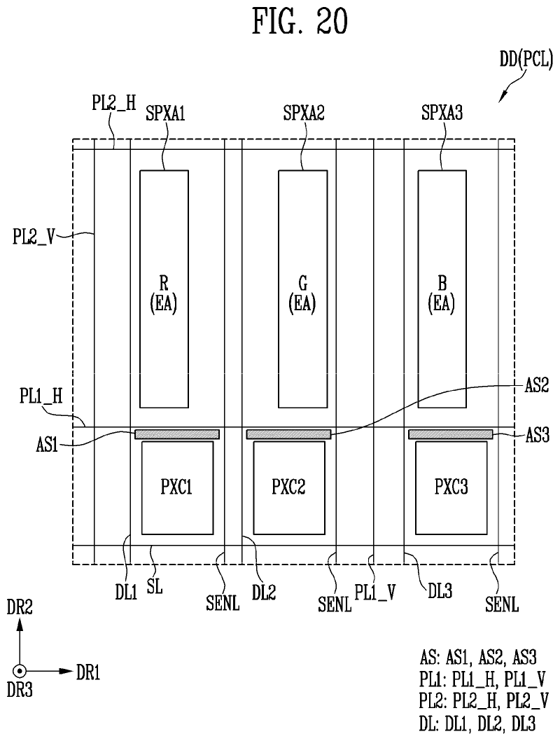

FIGS. 18 and 19 are schematic cross-sectional views illustrating a structure of a display device DD including a light non-transmissive layer AS according to another embodiment. FIGS. 18 and 19 show a cross-sectional structure of the display device DD including the light non-transmissive layer AS. FIG. 20 is a schematic plan view illustrating a structure of a display device DD including a light non-transmissive layer AS according to another embodiment. FIG. 20 shows a planar structure of the display device DD including the light non-transmissive layer AS.

The display device DD according to another embodiment and the display device DD according to an embodiment may be different in that the display device DD according to the another embodiment includes the light non-transmissive layer AS.

The light non-transmissive layer AS may not transmit at least a portion of applied light.

According to an embodiment, the light non-transmissive layer AS may absorb at least a portion of the applied light. For example, the light non-transmissive layer AS may include a light absorbing material. The light non-transmissive layer AS may include graphite or the like.

In another embodiment, the light non-transmissive layer AS may reflect at least a portion of the applied light. For example, the light non-transmissive layer AS may include a light reflecting material. The light non-transmissive layer AS may include a reflective metal. However, the disclosure is not limited thereto.

According to an embodiment, the light non-transmissive layer AS may be disposed on the base layer BSL. For example, the light non-transmissive layer AS may be covered by the buffer layer BFL on the base layer BSL. However, the disclosure is not necessarily limited thereto. For example, the light non-transmissive layer AS may be covered by an insulating layer of the pixel circuit layer PCL other than the buffer layer BFL.

The light non-transmissive layer AS may be disposed between the lower lines BPL and the electrode-free area EFA in a plan view. The light non-transmissive layer AS may be disposed between the lower lines BPL and the light emitting element LD in a plan view.

Since the light non-transmissive layer AS may be disposed between the lower lines BPL and the electrode-free area EFA in a plan view, the rear surface light RL may be prevented from being applied to at least a portion of the lower lines BPL. For example, since the light non-transmissive layer AS may be disposed between the first transistor M1 and the electrode-free area EFA in a plan view, a risk that the rear surface light RL is transmitted to at least a portion (for example, the first active layer ACT1) of the first transistor M1 may be prevented.

The light non-transmissive layer AS may be disposed adjacent to the circuit element of the pixel circuit PXC, and a structure for controlling the light path may be provided.

According to an embodiment, the light non-transmissive layer AS may include one or more light non-transmissive layers AS1, AS2, and AS3 spaced apart from each other in the first direction DR1. For example, the light non-transmissive layer AS may include a first light non-transmissive layer AS1, a second light non-transmissive layer AS2, and a third light non-transmissive layer AS3. According to an embodiment, the first light non-transmissive layer AS1, the second light non-transmissive layer AS2, and the third light non-transmissive layer AS3 may be sequentially disposed in the direction in which the first to third pixel circuits PXC1, PXC2, and PXC3 are sequentially disposed (for example, the first direction DR1).

The light non-transmissive layer AS may be disposed at a position corresponding to a position at which the above-described inner hole IH is disposed, in a plan view.

The light non-transmissive layer AS may be disposed between the emission area EA and the pixel circuit PXC in the second direction DR2 in a plan view. For example, the first light non-transmissive layer AS1 may be disposed between the first emission area R and the first pixel circuit PXC1 in the second direction DR2 in a plan view. The second light non-transmissive layer AS2 may be disposed between the second emission area G and the second pixel circuit PXC2 in the second direction DR2 in a plan view. The third light non-transmissive layer AS3 may be disposed between the third emission area B and the third pixel circuit PXC3 in the second direction DR2 in a plan view.

The light non-transmissive layer AS may not overlap the emission area EA and the pixel circuit PXC in the first direction DR1 in a plan view. For example, the first light non-transmissive layer AS1 may not overlap the first emission area R and the first pixel circuit PXC1 in the first direction DR1 in a plan view. The second light non-transmissive layer AS2 may not overlap the second emission area G and the second pixel circuit PXC2 in the first direction DR1 in a plan view. The third light non-transmissive layer AS3 may not overlap the third emission area B and the third pixel circuit PXC3 in the first direction DR1 in a plan view.

According to an embodiment, the light non-transmissive layer AS may be disposed between the first-first power line PL1_H and the first transistor M1. For example, the light non-transmissive layer AS may be disposed between the first source electrode SE1 of the first transistor M1 and the first-first power line PL1_H in a plan view. Accordingly, the light non-transmissive layer AS may be disposed in the line-free area BFA in which the lower lines BPL are not disposed.

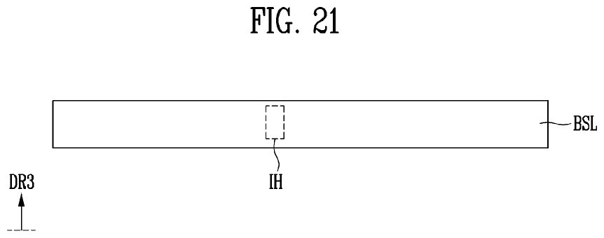

A method of manufacturing a display device DD according to an embodiment is described with reference to FIGS. 21 to 24.

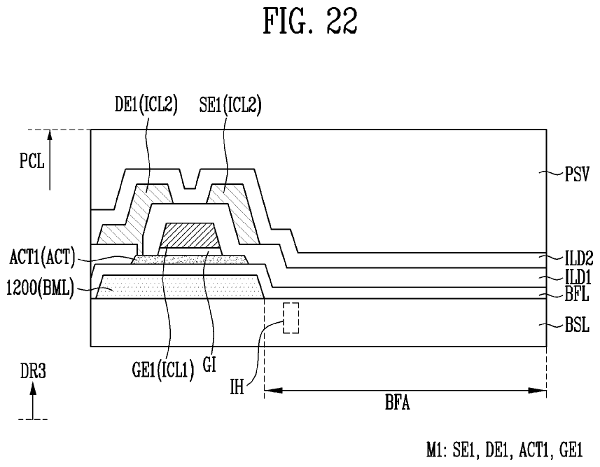

FIGS. 21 and 22 are schematic cross-sectional views illustrating a method of manufacturing the display device DD according to an embodiment.

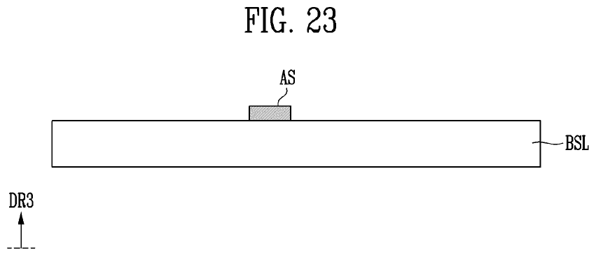

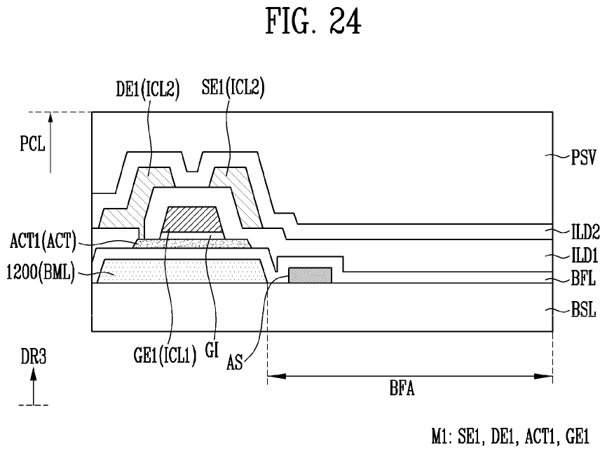

FIGS. 23 and 24 are schematic cross-sectional views illustrating a method of manufacturing the display device DD according to another embodiment.

In FIGS. 21 and 22, a method of manufacturing the display device DD including the inner hole IH is described in connection.

Referring to FIG. 21, an inner hole IH may be formed in a base layer BSL.

According to an embodiment, the base layer BSL may be prepared, and a laser process for forming the inner hole IH in the base layer BSL may be performed. At least a portion of the base layer BSL may be removed by performing the laser process.

For example, the laser process may include a laser processing using a femtosecond laser or the like. The femtosecond laser may form the inner hole IH while minimizing damage to an upper portion of the base layer BSL covering the inner hole IH. According to an embodiment, a laser process using a bessel beam may be performed so that the inner hole IH has one or more sub-inner holes SIH.

Referring to FIG. 22, a pixel circuit layer PCL may be formed on the base layer BSL.

According to an embodiment, in order to manufacture the pixel circuit layer PCL, one or more conductive layers (see, e.g., ACT, ICL1, ICL2, and ELT of FIG. 5) and insulating layers (see, e.g., GI, ILD1, and ILD2 of FIG. 5) may be patterned on the base layer BSL. According to an embodiment, configurations (for example, the lower lines BPL) disposed on the base layer BSL may be formed through a normal patterning process (for example, a photolithography process or the like) using a mask. For example, the first transistor M1 may be patterned on the base layer BSL.

According to an embodiment, the lower lines BPL may not be disposed in at least a partial area, and the line-free area BFA may be formed in the step.

According to an embodiment, the lower lines BPL may be patterned so as not to overlap the inner hole IH in a plan view. Accordingly, the inner hole IH may be disposed in the line-free area BFA in a plan view.

Thereafter, referring to FIGS. 7, 9 and 10, the alignment electrodes ELT may be patterned on the pixel circuit layer PCL. The light emitting elements LD may be aligned between the alignment electrodes ELT. As described above, the light emitting elements LD may be aligned based on the electric field formed between the first electrode ELT1 and the second electrode ELT2.

A method of manufacturing the display device DD including the light non-transmissive layer AS is described with reference to FIGS. 23 and 24 and with reference to the above-described drawings together. Compared to the manufacturing method according to the above-described embodiment, a difference is described.

Referring to FIG. 23, a base layer BSL may be prepared, and a light non-transmissive layer AS may be patterned on the base layer BSL. The light non-transmissive layer AS may be disposed in a partial area so as not to overlap the lower lines BPL in a plan view that is patterned in a subsequent process.

The light non-transmissive layer AS may include one or more of the materials described above, and may be formed using a patterning process.

Referring to FIG. 24, a pixel circuit layer PCL may be formed on the base layer BSL.

According to an embodiment, the light non-transmissive layer AS may be covered by the buffer layer BFL. The first transistor M1 may not overlap the light non-transmissive layer AS in a plan view and may be disposed adjacent to the light non-transmissive layer AS. Since the light non-transmissive layer AS may not overlap the lower lines BPL in a plan view, the light non-transmissive layer AS may be disposed in the line-free area BFA. Accordingly, the light non-transmissive layer AS may block at least a portion of light transmitted to a portion (for example, the first transistor M1) of the pixel circuit PXC.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a base layer comprising an inner hole;
a pixel circuit layer disposed on the base layer and comprising a pixel circuit; and
a light emitting element disposed on the pixel circuit layer.

2. The display device according to claim 1, wherein the inner hole forms an air-pocket in the base layer.

3. The display device according to claim 2, wherein the inner hole forms an interface with an inner surface of the base layer.

4. The display device according to claim 1, wherein
the pixel circuit layer further comprises lower lines, at least a portion of the lower lines forming the pixel circuit,
the display device further comprises a line-free area in which the lower lines are not disposed, and
the inner hole and the line-free area do not overlap with each other in a plan view.

5. The display device according to claim 4, further comprising:
a first electrode and a second electrode spaced apart from each other on the pixel circuit layer; and
an electrode-free area defined by a space between the first electrode and the second electrode, wherein
the light emitting element is disposed between the first electrode and the second electrode in a plan view, and
the electrode-free area is entirely disposed in the line-free area in a plan view.

6. The display device according to claim 5, wherein the electrode-free area overlaps the light emitting element in a plan view.

7. The display device according to claim 5, wherein the inner hole is disposed between the lower lines and the electrode-free area in a plan view.

8. The display device according to claim 7, wherein
the pixel circuit comprises a driving transistor, and
the inner hole is disposed between the driving transistor and an emission area, in which the light emitting element is disposed, in a plan view.

9. The display device according to claim 8, wherein
the inner hole comprises a first inner hole, a second inner hole, and a third inner hole,
the pixel circuit comprises a first pixel circuit, a second pixel circuit, and a third pixel circuit, and
the first inner hole, the second inner hole, and the third inner hole are arranged in a first direction parallel to a direction the first pixel circuit, the second pixel circuit, and the third pixel circuit are sequentially arranged.

10. The display device according to claim 9, wherein
the emission area comprises a first emission area, a second emission area, and a third emission area arranged in the first direction,
the first inner hole is disposed between the first pixel circuit and the first emission area in a plan view,
the second inner hole is disposed between the second pixel circuit and the second emission area in a plan view, and
the third inner hole is disposed between the third pixel circuit and the third emission area in a plan view.

11. The display device according to claim 9, wherein the inner hole has a shape extending in the first direction.

12. The display device according to claim 9, wherein the inner hole comprises more than one sub-inner holes sequentially arranged in the first direction.

13. The display device according to claim 9, wherein
the inner hole comprises more than one sub-inner holes sequentially arranged in a second direction different from the first direction.

14. A display device comprising:
a light non-transmissive layer disposed on a base layer;
a pixel circuit layer disposed on the base layer and comprising lower lines, at least a portion of the lower lines forming a pixel circuit; and
a light emitting element disposed on the pixel circuit layer, and
a line-free area in which the lower lines are not disposed,
wherein the light non-transmissive layer is disposed in the line-free area adjacent to the pixel circuit.

15. The display device according to claim 14, wherein the light non-transmissive layer comprises a light absorbing material or a light reflecting material.

16. The display device according to claim 14, further comprising:
a first electrode and a second electrode spaced apart from each other on the pixel circuit layer; and
an electrode-free area defined by a space between the first electrode and the second electrode, wherein
the light emitting element is disposed between the first electrode and the second electrode in a plan view,
the pixel circuit comprises a driving transistor, and
the light non-transmissive layer is disposed between the driving transistor and the electrode-free area in a plan view.

17. A method of manufacturing a display device, the method comprising:
preparing a base layer for manufacturing a display device; and
forming an inner hole in the base layer.

18. The method according to claim 17, wherein the forming of the inner hole comprises removing at least a portion of the base layer using a femtosecond laser.

19. The method according to claim 17, further comprising:
forming a pixel circuit layer comprising lower lines, at least a portion of which forming a pixel circuit, on the base layer;
patterning a first electrode and a second electrode on the pixel circuit layer; and
arranging a light emitting element on the first electrode and the second electrode, wherein
the display device comprises an electrode-free area in which the first electrode and the second electrode are spaced apart from each other,
the pixel circuit comprises a driving transistor, and
the inner hole is disposed between the driving transistor and the electrode-free area in a plan view.

20. The method according to claim 19, wherein the arranging of the light emitting element comprises:
forming an electric field between the first electrode and the second electrode; and
aligning the light emitting element based on the electric field.
